(19) United States
(12) Patent Application Publication
(10) Pub. No.: US 2026/0128739 A1
(43) Pub. Date: May 7, 2026

(54) SEMICONDUCTOR SWITCH

(71) Applicant: Cambridge GaN Devices Limited, Cambridge (GB)

(72) Inventors: Florin UDREA, Cambridge (GB); Martin ARNOLD, Cambridge (GB); David MILLER, Cambridge (GB); Daniel POPA, Cambridge (GB); Pooja SHARMA, Cambridge (GB); Ahmad Bin ARSHAD, Cambridge (GB); Juris ARROZY, Cambridge (GB); Krzysztof DEBOWSKI, Cambridge (GB)

(21) Appl. No.: 19/424,737

(22) Filed: Dec. 18, 2025

Related U.S. Application Data
(63) Continuation-in-part of application No. 18/393,946, filed on Dec. 22, 2023.

(30) Foreign Application Priority Data
Sep. 18, 2023 (GB) 2314270.6

(51) Int. Cl. H03K 17/284; H03K 17/081; H03K 17/14

(52) U.S. Cl. CPC H03K 17/284; H03K 17/08104; H03K 17/145

(57) ABSTRACT

A semiconductor switch comprising a first main terminal, a second main terminal, and a control terminal, the semiconductor switch comprising: a high voltage HEMT, the high voltage HEMT comprising a high voltage HEMT source terminal, a high voltage HEMT drain terminal, and a high voltage HEMT gate terminal; a control circuit; and a high voltage transistor device, the high voltage transistor device comprising a transistor device first terminal, a transistor device second terminal, and a transistor device gate terminal; wherein the high voltage HEMT source terminal and the transistor device first terminal are operatively connected to the first main terminal; wherein the high voltage HEMT drain terminal and the transistor device second terminal are operatively connected to the second main terminal; and wherein the high voltage HEMT gate terminal and the transistor device gate terminal are operatively connected to the control terminal via the control circuit.

### TECHNICAL FIELD

The present disclosure relates to a semiconductor switch. Particularly, but not exclusively, the disclosure relates to a parallel switch based on a high-electron-mobility transistor (HEMT) (e.g. a III-nitride HEMT) and a high voltage transistor device such as an insulated-gate bipolar transistor (IGBT), a metal-oxide-semiconductor field-effect transistor (MOSFET), or a superjunction. The high voltage transistor device may be a silicon or silicon carbide device.

### BACKGROUND

### IGBTs

Insulated Gate Bipolar transistors (IGBTs) are silicon devices that employ bipolar conduction while maintaining MOS gate control. The bipolar conduction allows for conductivity modulation of the drift region which in turn results in low on-state resistance. The conductivity modulation depends on the current density level. Above a certain current density level (e.g. 0.1 A/cm2), the excess charged (plasma) brought by the bipolar injection of holes and electrons could be larger than the doping charge level of the drift region and therefore resulting an increase in the conductivity of the drift region. The higher the current density, the larger the plasma created in the drift region and therefore the lower the on-state resistance of the drift region. IGBTs are used as switches in high voltage and high power applications. Their typical blocking voltage range is very wide, from 600 V to 6.5 kV, while typical current range is also very wide and varies from a few Amps to thousands of Amps. The on-state voltage drop across the drift region (the region that blocks the voltage during off-state) is directly proportional to the on-state resistance and therefore a smaller on-state resistance results in a lower voltage drop and a more efficient device in the on-state. The simplest equivalent circuit description of an IGBT is that of a metal-oxide-semiconductor field-effect transistor (MOSFET) device driving the base terminal of a bipolar transistor. Most IGBTs are n-channel devices. For these the MOSFET is an n-channel and the transistor is a pnp transistor. The base region of the pnp transistor is the n-type doped drift region of the IGBT. The total on-state voltage drop of the IGBT is approximately given by the sum of the voltage drop across the base-emitter junction of the pnp transistor, the voltage drop across the drift region and the voltage drop across the n-channel of the MOSFET component. The IGBT conducts no current until the base-emitter junction of the pnp transistor is forward-biased. For this, at room temperature, a minimum voltage drop of 0.7 V (at room temperature) is needed between its main terminals. The collector terminal of the IGBT is defined as the high voltage terminal in the forward conduction, while the emitter terminal is defined as the low voltage terminal in the forward conduction. The gate terminal modulates the channel resistance and therefore modulates the electron injection into the base of the pnp transistor.

Note that the collector terminal of the IGBT is in fact the emitter terminal of the pnp transistor and the emitter terminal of the IGBT is in fact both the collector terminal of the pnp transistor and the source terminal of the MOSFET component. The collector junction of the IGBT is the same as emitter-base junction of the PNP transistor.

The IGBT has superior on-state characteristics but in general is quite slow due to the need to build and remove the plasma (excess charge of minority carriers, electrons and holes in equilibrium) during the turn-on and turn-off transients. In particular the removal of the plasma is a slow process dictated by (i) the sweeping action of the depletion region, when the voltage builds up in the depletion region and (ii) by the recombination of carriers.

The IGBT does not conduct until 0.7 V at room temperature. This voltage level goes down as the temperature is increased. The rate at which it goes down is ˜1.5 to 2 mV/degC. Nevertheless this is considered a weakness of the IGBT.

IGBTs are used extensively in motor control applications and they tend to operate at relatively lower frequencies (e.g. 1 to 30 kHz). One of their important applications is that of inverters in electric cars. Here 6 IGBTs (or 6 sets of IGBTs connected in parallel) are used as three half bridges per each of the three phases driving a motor.

IGBTs have an interesting temperature behavior. At relatively low on-state voltage drops (low currents) the IGBTs have a negative temperature coefficient—meaning that their on-state voltage drop decreases with temperature while at relatively higher on-state voltage drops (higher currents) the IGBTs have a positive temperature coefficient—meaning that their on-state voltage drop increases with temperature. At low currents the bipolar effect is prominent while at higher currents and eventually during the channel saturation, the MOSFET effect becomes prominent. For a nominal current the IGBTs are generally designed to have a mild positive temperature coefficient, meaning that their voltage drop increases slightly with temperature. This is a good compromise between avoiding high on-state losses at high temperatures while allowing for easy-paralleling and avoiding runaway thermal effects.

The IGBTs have good short-circuit capability and limited avalanche capability. They also have good reliability and most IGBTs are rated for a maximum junction temperature of 175° C.

### Silicon Carbide

Silicon Carbide MOSFETs are unipolar devices (during forward conduction) and are considered good alternatives to the IGBTs. They are faster and they do not have the IGBTs 0.7 V weakness. Unlike silicon MOSFET and silicon Superjunctions, Silicon Carbide MOSFETs and Silicon Carbide superjunctions do not suffer from a very high positive temperature coefficient and in this way they match the high performance of the IGBTs at high temperatures. While the drift mobility decreases with temperature, the channel mobility remains constant or even slightly increases with temperature. Silicon Carbide MOSFETs and Silicon Carbide Superjunctions are among the state-of-the-art devices today. When compared to Power MOSFET superjunctions, they have a lower specific on-state drift resistance due to the presence of n-type and p-type pillars in the drift region to further reduce the resistivity of the drift region. Nevertheless, the process of making n/p pillars within the drift region is complex leading to further increase in the cost.

In general, silicon carbide wafers and device processing are still significantly more expensive than those of silicon. Moreover, Silicon Carbide MOSFETs have lower short-circuit capability than the IGBTs and are vulnerable to threshold voltage instabilities and reliability effects during the bipolar reverse conduction.

In applications such as motor control (e.g. inverters in electric cars), the currently preferred devices are vertical switches. Bipolar devices in silicon such as IGBTs or silicon Carbide MOSFETs are the main switches in this market.

IGBTs are widely available, have relatively low cost, and they are currently manufactured in 12 inch wafers. As mentioned, their on-state performance is very good especially at high currents and/or high temperature. However, they only conduct forward currents above 0.7V (at room temperature) and therefore tend to be less efficient in low to medium load conditions. Silicon Carbide MOSFETs on the other hand are expensive and their availability is scarcer.

To scale-up in current (up to values of 1000 A), chips of IGBTs or SiC are placed in parallel within a module. In this way, very large area chips are avoided. This has the advantage of higher yield and creating multiple heat sources which results in a lower temperature increase.

Parallel combinations of Silicon Carbide MOSFETs and IGBTs have also been proposed in the prior art as shown in FIG. 1, which shows an IGBT in parallel with Silicon Carbide MOSFET, reproduced from M. Rahimo, IEEE TRANSACTIONS ON POWER ELECTRONICS, VOL. 30, NO. 9, SEPTEMBER 2015, the contents of which are hereby incorporated by reference.

The silicon carbide MOSFET can conduct the forward current up to 0.7 V while both the IGBT and SiC can conduct above 0.7 V. However, the IGBTs and the SiC MOSFETs and superjunctions are vertical devices and therefore cannot integrate any smartness. No monolithic integration of sensing and protection features are present in state-of-the-art IGBTs and SiC MOSFETs.

### GaN HEMT

Gallium Nitride (GaN) has been more recently considered as a very promising material for use in the field of power devices. The application areas range from portable consumer electronics, solar power inverters, electric vehicles, and power supplies. The wide band gap of the material (Eg=3.39 eV) results in high critical electric field (Ec=3.3 MV/cm) which can lead to the design of devices with a shorter drift region, and therefore lower on-state resistance if compared to a silicon-based device with the same breakdown voltage.

The use of an Aluminium Gallium Nitride (AlGaN)/GaN heterostructure also allows the formation of a two-dimensional electron gas (2DEG) at the hetero-interface where carriers can reach very high mobility [μ=2000 cm2/(Vs)] values. In addition, the piezopolarization charge present at the AlGaN/GaN heterostructure, results in a high electron density in the 2DEG layer (e.g. 1×1013 cm-2). These properties allow the development of High Electron Mobility Transistors (HEMTs) and Schottky barrier diodes with very competitive performance parameters. One common parameter used to compare power semiconductor transistors is Specific ON-state resistance or Specific Rds(ON). The specific Rds(ON) is the product of the resistance of a device times the area of the device on wafer. An extensive amount of research has focused on the development of power devices using AlGaN/GaN heterostructures.

Layers which constitute the AlGaN/GaN heterojunction transistor are often epitaxially grown on a substrate from a different material for example Silicon, Silicon Carbide or Sapphire. Epitaxial growth of GaN on different substrates has advantages and disadvantages both in terms of the complexity and cost of growing high quality layers and in terms of device performance. A non-exhaustive list of things to consider when choosing a suitable substrate is: substrate lattice constant mismatch with GaN, substrate thermal expansion coefficient mismatch with GaN, substrate cost, substrate thermal conductivity etc. Today, substrates such as silicon (using a transition layer to adapt the mismatch between GaN layers and silicon), semi-insulating silicon carbide, quartz and sapphire are present in the market or in advanced research.

GaN transistors based on a 2DEG are mainly available on a lateral configuration. While this is advantageous from a point of view of integrating additional smart circuits around the main power device, it does pose some limitations in terms of scalability at high currents (in excess of 100 A). Moreover, lateral GaN devices tend to be limited today to below 900 V rating, though this limit is expected to grow to 1.2 kV and beyond in the future.

There are different types of the gate structure available for GaN HEMTs. The p-Gan Gate features a layer of Magnesium doped GaN above the AlGaN layer. It delivers a positive threshold voltage of 1.3 to 1.7 V and results in an enhancement mode (normally-off) transistor. Currently this is the preferred solution in the market. The p-GaN gate technology has also some major disadvantages. If the gate voltage applied to the gate is in excess of 7 V the leakage current becomes very high leading to failure. Moreover, the relatively low threshold voltage does not give sufficient margin for avoiding retriggering on the transistor during the turn-off if the minimum voltage level is zero (ground). For this reason, often such transistors need negative voltage rails which make the driving more cumbersome and could result in some reliability issues such as the dynamic increase in the Rds(ON).

Other alternative technologies are based on an insulated gate or Schottky gate. The insulated gate is problematic for GaN due to traps in the insulated material and at the interface between the GaN or AlGaN and the insulated material. While this could deliver a higher threshold voltage, the reliability and reproducibility are currently poor and therefore there are no devices of this type in the market. The Schottky gate results in normally-on devices (depletion mode devices), which could only be used in a Cascode configuration or direct drive mode to deliver a normally-off solution. The Cascode relies on placing a silicon MOSFET in series with a depletion mode HEMT (based on Schottky gate technology) with the gate of the HEMT connected to the source of the silicon MOSFET and the drain of the Silicon MOSFET connected to the source of the depletion mode HEMT. The main advantage of this solution is the gate of the Cascode device is the insulated gate of the MOSFET which has a high degree of reliability, ease of use and can be easily tailored for a higher threshold voltage and extended voltage range. No negative voltage rail is needed. However, both the Cascode and direct drive configurations are based on two chip solution. Moreover, adjusting the slew rate in the Cascode configuration is not straightforward, as the gate of the depletion mode HEMT has a fixed potential (connected to the source of the MOSFET and not to the driver). While these solutions (i.e. direct drive and Cascode) are present in the market, they have a strong competition from enhancement gate GaN solutions.

It would be of interest to parallel GaN HEMTs with vertical devices such as IGBTs or SiC devices such as Power MOSFETs or Superjunctions. A simple, but problematic combination is shown in FIG. 2. GaN HEMTs are especially efficient at low on-state voltage drops, low on-state currents and lower temperatures, while devices such as IGBTs are inefficient at low currents (due to the forward voltage drop on the base-emitter junction of the pnp transistor) but have superior on-state characteristics at high currents and higher temperatures.

However, enhancement GaN devices cannot be easily paralleled with vertical devices such as IGBTs and/or SiC MOSFETs and/or SiC superjunctions. The gate voltage range for vertical devices is not aligned to that of the p-GaN HEMTs. P-GaN HEMTs tend to have a threshold voltage of around 1.5 V while IGBTs and SiC power MOSFETs and superjunctions have threshold voltages in excess of 3V (e.g. 4V). The maximum drive voltage for the p-GaN HEMT (to turn-on of the device and maintain it in the on-state) is limited to 7V, before the leakage current through the gate becomes too large. In contrast, IGBTs, SiC MOSFETs and Superjunctions are driven with a maximum voltage in excess of 10 V, and often in excess of 15 V (e.g. 20V). If the HEMT could be done with an insulated gate instead of a p-GaN gate, the threshold could be adjusted and the voltage range could be extended. However, insulated gate HEMTs are not currently available and the technology is not ready for the market as explained above.

Another approach in paralleling a HEMT with a vertical switch (in this case an IGBT) has been described by L. Molnar, 2018 IEEE 24^{th} International Symposium for Design and Technology in Electronic Packaging (SIITME), 2018, the contents of which is hereby incorporated by reference (FIG. 3). The circuit implementation provided in FIG. 3 is however very complex with each of the GaN HEMT and the IGBT having a separate gate driver and a common digital control circuit. Furthermore, a monitor feedback circuit is also added for better sharing of current between the two components. The solution is too complex and not cost effective in high power applications.

### SUMMARY

Aspects and preferred features are set out in the accompanying claims.

The present disclosure provides a semiconductor switch combining a high-electron-mobility transistor (HEMT), and another transistor device that may be, for example, an insulated-gate bipolar transistor (IGBT), a metal-oxide-semiconductor field-effect transistor (MOSFET), or a superjunction. The HEMT may be a lateral device, made in III-nitride material while the transistor device may be a vertical device, preferably made in silicon or silicon-carbide. Alternatively, the vertical device may be made in Vertical GaN, GaN on GaN or ultra wide bandgap materials such as Gallium Oxide (GaO) or Aluminium Nitride (AlN). While the HEMT and the other transistor device can be based on different material systems, the semiconductor switch according to the present disclosure can enable both devices to be driven using a single control terminal, rather than requiring a dedicated driver for each device. Moreover, given the lateral configuration, other devices or circuits can be monolithically integrated with the HEMT, for sensing and protection, for voltage regulation and for enhanced reliability.

In some examples described herein, the semiconductor switch is referred to as a “combined switch”.

In some examples, as already mentioned, the HEMT may be a III-nitride based device, and the high voltage transistor device may be a silicon or silicon carbide based device. The silicon device may be an Insulated Gate Bipolar Transistor (IGBT) while the silicon carbide based device may be a Power MOSFET or a superjunction.

In some examples, driving voltage compatibility between the HEMT and the transistor device is achieved by having the HEMT form part of an integrated circuit, the integrated circuit further comprising an interface circuit operatively connected to the gate terminal of the HEMT and to the control terminal of the semiconductor switch. In some examples the interface circuit comprises an auxiliary HEMT to achieve driving voltage compatibility between the HEMT and the transistor device.

It is an aim of this disclosure to create a switch based on a parallel combination between a lateral GaN HEMT and a vertical high voltage device and featuring a single control terminal which could drive directly or indirectly both the GaN HEMT and the vertical device. The switch according to this disclosure needs a single, common drive circuit, placed preferably externally, rather than a dedicated driver for each of the devices. Moreover, such a combined chip could be co-packaged, in a system in package (SIP) technology or packaged within a module or embedded in a PCB, such that from the outside, the switch resembles a single chip. The vertically high voltage device is preferably an IGBT. Alternatively, it could be a Silicon Carbide device such as a Power MOSFET or a Superjunction.

The module or embedded package or SIP may contain a parallel combination between several HEMT switches and several vertical high voltage devices. This could be seen as a parallel combination of several combined switches according to this disclosure.

The combined switch according to the present disclosure takes advantage of the superior characteristics of the vertical switch at high currents and high temperature (medium to full load) and the superior performance of the lateral GaN HEMT at low currents and lower temperatures (light load). The lateral GaN HEMT could also provide sensing and protection functions which could benefit both the high voltage GaN HEMT and the overall combined switch. The sensing and protection functions may be monolithically integrated (within the same chip) with the high voltage lateral GaN HEMT.

The combined switch could be seen as a single high voltage switch with two main terminals, a low voltage terminal (Terminal 1—T1) and a high voltage terminal (Terminal 2—T2) and a control terminal, as well as potentially further terminals such as current sense terminal, DC low voltage rail terminal (VDD), short-circuit protection terminal and Kelvin.

According to a first aspect of this disclosure, an interface is placed in front of the gate of the high voltage lateral GAN HEMT to adapt the driving voltage of the control terminal to that suitable and allowable for the GAN HEMT. For example, the driving voltage on the gate terminal could be from 0 to 20 V while the driving voltage seen directly by the gate terminal of the lateral high voltage GaN HEMT remains 0 to 7V. The interface may contain other clamping circuits, sensing and protection functions, pull-down devices to ensure a fast and safe turn-off, to enhance immunity against dV/dt and to absorb any transient voltage peaks on the gate. Other sensing and protection functions could also be incorporated.

In an example according to the present disclosure, the interface is or comprises a low voltage GaN HEMT (Auxiliary HEMT or Aux HEMT) in front of the intrinsic gate of the high voltage GaN HEMT to absorb any differences in the voltage between the voltage applied to the control terminal of the combined switch (which for example could go up to 20 V) and that of the gate of the lateral GaN HEMT (which for the p-GaN gate structure could only go up to ˜7 V). Furthermore, the addition of the low voltage GaN HEMT allows for an increase in the threshold voltage (wherein the threshold voltage in this context may refer to the voltage applied between the control terminal and the GaN HEMT source terminal) at which the high voltage GaN HEMT turns-on and this could be matched or be closer to the threshold voltage of the vertical switch (typically larger than 3 V).

The combined switch could be driven with voltages between 0V and 20 V (or—5 V to 20 V if desired).

Additional devices and circuits could be integrated monolithically with the High Voltage GaN HEMT. In other words, the combined switch can be described as a GaN Power Integrated Circuit (GaN Power IC) in parallel with a high voltage device (e.g. IGBT). Besides the Aux HEMT and the high voltage GaN HEMT, the GaN power IC could conveniently incorporate (monolithically integrated) other devices and/or circuits, such as a Miller clamp HEMT (pull-down device), voltage regulators, Current Sources, Current sense HEMTs, Sensing load resistor, Slew rate control circuit, dV/dt control drive circuits, short-circuit detection and protection circuits, over current and over temperature protection circuits, start-up devices/circuits, Electro-static Discharge (ESD) devices or circuits, logic circuits, capacitors, resistors and diodes (e.g. Schottky diodes or diodes made of a HEMT transistor by connecting the gate to one of its other terminals, source or drain). Some of these circuits/devices and their use have been disclosed in detail in, for example, US2020/0168599, US2020/0357909, U.S. Pat. No. 10,818,786, US2021/0335781, and US20230131602, the contents of all of which are hereby incorporated by reference.

Multiple high voltage GaN HEMTs could be placed in parallel with the IGBT. Similarly, multiple IGBTs could be used in parallel with one or multiple high voltage GaN HEMTs. This could be preferred for higher power applications or for thermal reasons (as multiple heat sources rather than a single cumulative heat source results in lower maximum temperature increase). A single AUX HEMT could be placed in the gate of the multiple GaN devices. Alternatively, individual GaN HEMTs (and possibly individually placed Miller Clamps/pull down devices/circuits) could be connected to each of the high voltage GaN HEMTs. Possibly parallel GaN power ICs further connected in parallel with an IGBT (or other vertical device or multiple parallel vertical devices) could be used in the combined switch.

The IGBT may be a reverse conducting IGBT (RC-IGBT) and therefore could incorporate a reverse conducting bipolar diode. This diode could become in parallel with the unipolar reverse-biased diode of the GaN HEMT. The reverse-bias diode of the GaN HEMT may not be able to sufficiently carry out the reverse conducting current especially in applications where freewheeling is present. Therefore, the bipolar diode of the RC IGBT could be used for surge or for minimizing the reverse conduction losses.

Alternatively, an extra external high voltage diode could be placed in parallel with the combined switch for enhanced reversed conduction or for minimizing reverse recovery losses during the reverse recovery transients. The diode could be a silicon bipolar diode such as a PIN diode or could be a Silicon Carbide Schottky diode. Its blocking capability should be similar to that of the vertical power device (IGBT). State-of-the art Silicon Carbide Schottky diodes are superior to silicon diodes as they offer zero reverse conducting losses, but they are more expensive. A Silicon Carbide Junction Barrier Schottky diode featuring a combination of p+ rings and Schottky contact could be used for a good trade-off between a low leakage current and low on-state losses.

Described herein is semiconductor switch comprising a first main terminal, a second main terminal, and a control terminal, the semiconductor switch comprising:
a III-nitride integrated circuit, the III-nitride integrated circuit comprising:
a high voltage HEMT, the high voltage HEMT comprising a high voltage HEMT source terminal, a high voltage HEMT drain terminal, and a high voltage HEMT gate terminal; and
at least part of an interface circuit;
wherein the semiconductor switch further comprises a high voltage transistor device, the high voltage transistor device comprising a transistor device first terminal, a transistor device second terminal, and a transistor device gate terminal;
wherein the high voltage HEMT source terminal and the transistor device first terminal are operatively connected to the first main terminal;
wherein the high voltage HEMT drain terminal and the transistor device second terminal are operatively connected to the second main terminal; and
wherein the high voltage HEMT gate terminal is operatively connected to the control terminal via the interface circuit, wherein the interface circuit is configurable to adjust a voltage applied to the control terminal to be operatively compatible with the high voltage HEMT gate terminal.

It will be understood that the “vertical device” described herein generally refers to the high voltage transistor device.

The integrated circuit may comprise the whole III-nitride interface circuit, or the interface circuit may be partly disposed on a separate circuit (from the III-nitride integrated circuit). For example, the interface circuit may be partly disposed on a separate III-nitride or silicon circuit.

In some examples, the interface circuit comprises:
a low voltage auxiliary HEMT, the low voltage auxiliary HEMT comprising an auxiliary HEMT source terminal, an auxiliary HEMT drain terminal, and an auxiliary HEMT gate terminal; and
a voltage limiter operatively connected to the auxiliary HEMT gate terminal;
wherein the auxiliary HEMT source terminal is operatively connected to the high voltage HEMT gate terminal;
wherein the high voltage HEMT source terminal and the transistor device first terminal are operatively connected to the first main terminal;
wherein the high voltage HEMT drain terminal and the transistor device second terminal are operatively connected to the second main terminal;
wherein the auxiliary HEMT drain terminal is operatively connected to the control terminal; and
wherein the voltage limiter is operatively connected to the high voltage HEMT source terminal and to the auxiliary HEMT gate terminal, further wherein the voltage limiter is configurable to limit a voltage across the high voltage HEMT gate terminal and the high voltage HEMT source terminal.

The interface circuit may also be configured to perform other functions such as sensing and protection (e.g. current sensing and over-current protection). The interface circuit may comprise “smartness” or intelligence to aid a safe and reliable drive of the high voltage HEMT.

The interface circuit may for example be configured that higher currents (medium to full load conditions) and/or higher temperatures, the gate voltage of the HEMT could be lowered as to allow more current to flow through the first switch and thus protecting the GaN HEMT from over currents.

Preferably, the high voltage HEMT source terminal, the high voltage HEMT drain terminal, and the high voltage HEMT gate terminal are all disposed on a same surface of the high voltage HEMT (this may be referred to as a lateral arrangement or a lateral device).

Preferably, the transistor device first terminal and the transistor device gate terminal are disposed on a first side of the high voltage transistor device, and the transistor device second terminal is disposed on second side of the high voltage transistor device, opposite the first side of the high voltage transistor device (this may be referred to as a vertical arrangement or a vertical device).

In more detail, the high voltage HEMT is preferably based on a lateral arrangement wherein the main terminals (source, drain and gate terminals) are displaced laterally on the same surface of the device. The lateral HEMT may also contain a substrate terminal on the opposite surface (bottom surface). The substrate terminal may be operatively connected to the source terminal. Alternatively, the substrate may have a different potential to that of the source terminal or may be left floating. In a lateral arrangement, the on-state current flows largely laterally through the GaN HEMT from the drain to the source terminals and is modulated by the gate terminal to source terminal voltage.

The high voltage transistor device is preferably based on a vertical arrangement wherein the emitter/source and gate terminals are placed on the same surface (top surface) of the device and wherein the collector/drain terminal is placed on the opposite surface. In a vertical arrangement, the on-state current flows largely vertically through the high voltage transistor device from the collector/drain to the emitter/source terminals and is modulated by the gate terminal to emitter/source terminal voltage.

Further described herein is a semiconductor switch comprising a first main terminal, a second main terminal, and a control terminal, the semiconductor switch further comprising:
a high voltage high-electron-mobility transistor (HEMT), the high voltage HEMT comprising a high voltage HEMT source terminal, a high voltage HEMT drain terminal, and a high voltage HEMT gate terminal;
a low voltage auxiliary HEMT, the low voltage auxiliary HEMT comprising an auxiliary HEMT source terminal, an auxiliary HEMT drain terminal, and an auxiliary HEMT gate terminal;
a voltage limiter operatively connected to the auxiliary HEMT gate terminal; and
a high voltage transistor device, the high voltage transistor device comprising a transistor device first terminal, a second transistor device second terminal, and a transistor device gate terminal;
wherein the auxiliary HEMT source terminal is operatively connected to the high voltage HEMT gate terminal;
wherein the high voltage HEMT source terminal and the transistor device first terminal are operatively connected to the first main terminal;
wherein the high voltage HEMT drain terminal and the transistor device second terminal are operatively connected to the second main terminal;
wherein the auxiliary HEMT drain terminal and the transistor device gate terminal are operatively connected to the control terminal; and
wherein the voltage limiter is operatively connected to the high voltage HEMT source terminal and to the auxiliary HEMT gate terminal, further wherein the voltage limiter is configured, or configurable, to limit a voltage across the high voltage HEMT gate terminal and the high voltage HEMT source terminal.

The auxiliary HEMT described above could be part of an interface between the control terminal and the high voltage HEMT gate terminal.

The high voltage HEMT may be a III-nitride HEMT and preferably an enhancement mode (normally-off) device. The high voltage HEMT may be preferably designed to have a slightly higher breakdown voltage than the high voltage transistor device. Its breakdown may be limited by leakage rather than avalanche. In contrast the high voltage switch may break via avalanche before unacceptable high leakage is present in the high voltage HEMT. The high voltage transistor device can provide avalanche capability to the combined switch and can clamp the breakdown voltage of the combined switch to the avalanche voltage of the high voltage transistor device. As a result of this clamping effect, the high voltage HEMT may not need to be overengineered in terms of its own blocking capability, leading to smaller gate to drain or source to drain dimensions (or smaller GaN epi stack) and as a result lower specific on-state resistance Rds(ON). Note that in general stand-alone HEMTs are overengineered and they are designed to have a large margin between their rated voltage and the voltage at which leakage becomes very high. Here we take advantage of the avalanche provided by the vertical high voltage device, which means that the over engineering and the extra margin is not needed.

The auxiliary HEMT may be a III-nitride HEMT.

It will be understood that an operative connection may comprise, or may be, an electrical connection.

The high voltage transistor device may comprise a material, or materials system, other than a III-nitride material. In some examples, the high voltage transistor device is a silicon and/or silicon carbide transistor.

The high voltage HEMT and the auxiliary HEMT may be made in lateral configuration (that is to say that the main terminals are placed laterally displaced from each other on the same surface). The high voltage transistor may be made in a vertical configuration (that is to say that the main terminals may be on opposite surfaces and the current conduction is mainly vertical between such terminals).

It will be understood that the terms “high voltage” and “low voltage” as used herein are merely relative terms. The high voltage HEMT may equivalently be referred to as a “first HEMT”, and the low voltage auxiliary HEMT may equivalently be referred to as a “second HEMT”, or simply an “auxiliary HEMT”. Similarly, the high voltage transistor device may be referred to as simply a “transistor device”.

A “III-nitride” transistor, device, or integrated circuit, as used herein, may refer generally to a transistor or device based on the group III-nitride family of materials, including GaN, AlN, InN, and alloys thereof.

Advantageously, the auxiliary HEMT can absorb any difference in voltage between the voltage applied to the control terminal and the voltage of the gate terminal of the (e.g. lateral) high voltage HEMT. In addition, the auxiliary HEMT enables an increase in the threshold voltage at which the high voltage HEMT turns on, which may therefore be matched (or be made closer to) the threshold voltage of the (e.g. vertical) transistor device.

The auxiliary HEMT drain terminal may be operatively connected to the control terminal by a first resistance (e.g. a resistor, or a device or circuit providing a resistance).

Also described herein is a semiconductor switch comprising a first main terminal, a second main terminal, and a control terminal, the semiconductor switch comprising:
an integrated circuit, the integrated circuit comprising:
a high voltage HEMT, the high voltage HEMT comprising high voltage HEMT source terminal, a high voltage HEMT drain terminal, and a high voltage HEMT gate terminal; and
an interface circuit;
wherein the semiconductor switch further comprises a high voltage transistor device, the high voltage transistor device comprising a transistor device first terminal, a transistor device second terminal, and a transistor device gate terminal;
wherein the high voltage HEMT source terminal and the transistor device first terminal are operatively connected to the first main terminal;
wherein the high voltage HEMT drain terminal and the transistor device second terminal may be operatively connected to the second main terminal;
wherein the transistor device gate terminal is operatively connected to the control terminal; and
wherein the high voltage HEMT gate terminal is operatively connected to the control terminal via the interface circuit, wherein the interface circuit is configured, or configurable, to adjust a voltage applied to the control terminal to be operatively compatible with the high voltage HEMT gate terminal.

The integrated circuit may be a III-nitride integrated circuit.

The high voltage transistor device may comprise a material, or materials system, other than a III-nitride material. For example, preferably the high voltage transistor device is not a III-nitride transistor.

The voltage limiter could be made of one or several diodes or transistor like diodes put in series. Alternatively, a threshold amplification HEMT could be provided. A description of an example of a voltage limiter is provided in [US20230131602]. When the voltage limiter is provided with a forward current, the voltage drop across it saturates to a known voltage, the voltage limiter could be supplied with such forward current via a current source connected to the control terminal. A description of an example of a current source is provided in US20230131602.

The high voltage HEMT could preferably be a normally off HEMT (an enhancement mode HEMT). That means its threshold voltage is positive. The auxiliary HEMT could be either a normally-off (enhancement mode) or normally on (depletion mode) HEMT.

In some examples, the high voltage transistor device may be a silicon and/or silicon carbide transistor.

Advantageously, the interface circuit can absorb any difference in voltage between the voltage applied to the control terminal and the voltage of the gate terminal of the (e.g. lateral) high voltage HEMT. In addition, the interface circuit enables an increase in the threshold voltage at which the high voltage HEMT turns on, which may therefore be matched (or be made closer to) the threshold voltage of the (e.g. vertical) transistor device.

The provision of an integrated circuit may also advantageously enable monolithic integration of other circuits and devices, as described herein, to provide a compact and robust device package.

As described herein, the high voltage transistor device may comprise an insulated-gate bipolar transistor (IGBT). The transistor device first terminal may be an IGBT emitter terminal and the transistor device second terminal may be an IGBT collector terminal.

As described herein, the high voltage transistor device may comprise a metal-oxide-semiconductor field-effect transistor (MOSFET). The transistor device first terminal may be a source terminal (referred to as a MOSFET source terminal) and the transistor device second terminal may be a drain terminal (referred to as a MOSFET drain terminal).

As described herein, the high voltage transistor device may comprise a superjunction structure. The transistor device first terminal may be a source terminal (referred to as a superjunction source terminal) and the transistor device second terminal may be a drain terminal (referred to as a superjunction drain terminal).

In some examples, the transistor device gate terminal may be operatively connected to the control terminal via a resistance (which may be referred to as a second resistance) (e.g. a resistor, or a device or circuit providing a resistance and providing for example slew-rate control).

In some examples, the transistor device gate terminal may be operatively connected to an output of the interface circuit, e.g. such that the interface circuit may be configurable to control the transistor device.

In some examples, the high voltage HEMT source terminal, the high voltage HEMT drain terminal, and the high voltage HEMT gate terminal are laterally spaced from one another, e.g. the high voltage HEMT may be a lateral device.

In some examples, the transistor device first terminal and the transistor device second terminal are vertically spaced from one another, e.g. the high voltage transistor device may be a vertical device.

In some examples, the high voltage HEMT and the high voltage transistor device may be disposed on separate (e.g. different) substrates. For example, the high voltage HEMT may be disposed on a first semiconductor substrate, and the high voltage transistor device may be disposed on a second semiconductor substrate, different from the first semiconductor substrate.

For example, the semiconductor substrate on which the III-nitride high voltage HEMT is disposed may comprise silicon, silicon carbide, and/or sapphire.

The semiconductor switch may be configured to turn-on or be in an on-state when the control terminal is driven with a voltage of 10 V or more. The semiconductor switch may be configured to turn-off or be in an off-state when the control terminal is driven with a voltage of 0 V, or approximately 0 V. The semiconductor switch may be configured to turn off when the control terminal is driven with a voltage of less than a lower of: a threshold voltage of the high voltage HEMT; and a threshold voltage of the high voltage transistor device.

In some examples, the integrated circuit described herein further comprises one or more of:
A Miller clamp HEMT (or pull-down HEMT);
a pull-down circuit;
a voltage regulator;
a current source;
a sensing load resistor;
a slew rate control circuit;
a short-circuit detection circuit;
a protection circuit;
an over-current protection circuit;
an over-temperature protection circuit;
a dV/dt control circuit;
a drive circuit;
a start-up circuit;
an electrostatic discharge circuit;
a logic circuit;
a capacitor;
a resistor; and/or
a diode.

In some examples, the semiconductor switch described herein comprises a diode operatively connected between the first main terminal and the second main terminal, the diode comprising one or more of:
part of a reverse conducting IGBT;
part of a reverse conducting MOSFET;
a silicon carbide diode;
a Schottky diode;
a junction barrier Schottky diode;
a silicon diode; and/or
a bipolar diode.

In some examples, the semiconductor switch described herein comprises an integrated circuit, which may be referred to as a second integrated circuit, comprising one or more of:
a DC voltage regulator;
a slew rate control circuit;
a short-circuit detection circuit;
an over-current protection circuit;
an over-temperature protection circuit;
a dV/dt control circuit;
a drive circuit; and/or
a logic and/or timing circuit.

The second integrated circuit may be a silicon integrated circuit.

The range of blocking voltages for the semiconductor switch according to this invention can be from 100 V to 3.5 kV. In particular the range of 600V to 1.7 kV is of interest with various applications including in motor control and traction inverters. For the range of 600 V to around 900 V, the preferred substrate for the high voltage GaN HEMT could be silicon, though sapphire is also possible. Above 900 V (e.g. 1.2 kV), the quartz-based or semi-insulating SiC substrates could be used. Alternatively, a thick epi of GaN on silicon could be used to enhance the breakdown voltage,

The range of on-state currents for the combined switch can vary from Amps to thousands of Amps. The range of interest could be from 100Amps to 1000 Amps. Current can be increased by placing multiple switches in parallel. Within the switch it is preferable that the high voltage device (the vertical device) such as the IGBT, to have a higher current capability than the lateral HIGH Voltage HEMT. As an example, at full load the IGBT could carry 60 to 90% of the current while the high voltage HEMT can carry 40% to 10% of the current. This ratio could also be function of the ambient or the self-heating temperature. At higher temperatures it is expected that the ratio of the current in the vertical switch over that in the lateral high voltage HEMT may increase.

The switch is expected to operate at frequencies similar to those of the vertical device, as the GaN HEMT is expected to be faster than the vertical switch and therefore unlikely to largely limit the frequency of operation of the combined switch. If the vertical device is an IGBT, the frequency range may be below 100 kHz and if the vertical device is a Silicon Carbide MOSFET, the frequency may be below 500 kHz.

Series multiple GaN HEMTs could also be used in the combined switch. For example, two 650V GaN HEMTs (one on the low-side and one on the high side) could be placed in series with a 1.2 kV IGBT. This could be a favorable option as it is easier to make vertical devices at higher voltages than lateral HEMTs at higher voltages. An interface is still provided between the gate terminal of the low side high voltage HEMT and the control terminal. The high side GaN HEMT could be driven with the signal for the low-voltage GaN HEMT through an additional level shifter. The level shifter could be integrated with any of the high voltage GaN HEMTs.

According to a third aspect of the disclosure, there is provided a Cascode device in parallel with a high voltage device, wherein the high voltage device can be an IGBT, a silicon carbide MOSFET or superjunction.

For example, a semiconductor switch may comprise a first main terminal, a second main terminal, and a control terminal, the semiconductor switch comprising:
a Cascode device, the Cascode device comprising:
a MOSFET comprising a MOSFET drain terminal, a MOSFET gate terminal and a MOSFET source terminal;
a high voltage depletion mode III-nitride HEMT comprising a depletion HEMT drain terminal, a depletion HEMT gate terminal and a depletion HEMT source terminal;
wherein the MOSFET drain terminal is operatively connected to the depletion HEMT source terminal;
wherein the semiconductor switch further comprises a high voltage transistor device comprising a transistor device first terminal, a transistor device second terminal, and a transistor device gate terminal;
wherein the MOSFET source terminal and the transistor device first terminal are operatively connected to the first main terminal;
wherein the depletion HEMT drain terminal and the transistor device second terminal are operatively connected to the second main terminal;
wherein the MOSFET gate terminal is operatively connected to the control terminal.

The high voltage transistor device may comprise an IGBT, a silicon carbide MOSFET or a superjunction; and the MOSFET may comprise an n-channel MOSFET in vertical or quasi-vertical configuration.

The depletion HEMT gate terminal may be operatively connected to the MOSFET source terminal and the first main terminal; and
the transistor device gate terminal and the MOSFET gate terminal may be operatively connected to the control terminal.

The high voltage transistor device may comprise a bipolar junction transistor, and the depletion HEMT gate terminal may be operatively connected to the MOSFET source terminal and the first main terminal; and the transistor device gate terminal may be operatively connected to the MOSFET drain terminal and the depletion HEMT source terminal, and the MOSFET gate terminal may be operatively connected to the control terminal.

The high voltage transistor device may comprise a bipolar junction transistor, and the transistor device gate terminal may be operatively connected to the MOSFET drain terminal and the depletion HEMT source terminal, and the MOSFET gate terminal may be operatively connected to the control terminal, and the depletion HEMT gate terminal may be operatively connected to the control terminal via an interface circuit, and the interface circuit may be configured to adjust a voltage applied to the control terminal to be operatively compatible with the depletion HEMT gate terminal.

The Cascode device comprises a MOSFET in series with a depletion mode GaN HEMT. The gate of the depletion mode GaN HEMT is connected to the source of the MOSFET. The MOSFET could be preferably an n-channel MOSFET in vertical or quasi-vertical configuration. A blocking voltage of the MOSFET is preferably much smaller than that of the depletion mode HEMT. For example, the MOSFET blocking voltage could be 40 V for a 650V HEMT.

The gate of the MOSFET could be shorted to the gate of the high voltage switch (e.g. IGBT) and further connected to the control terminal of the combined switch. Alternatively, either of the gates could be connected to the control terminal via slew rate structures (which could be simply resistors or resistors with diodes).

According to a fourth aspect of this disclosure, an n-channel MOSFET is provided to drive the base of a high voltage PNP transistor (bipolar junction transistor) and concomitantly be connected to the source of a high voltage depletion mode HEMT. In this configuration the combined switch is based on the parallel conduction through a bipolar junction pnp transistor and through the Cascode device. The MOSFET is responsible for both (i) enabling a negative gate-source voltage for the depletion HEMT during the blocking mode and (ii) providing the electron current to the base of the pnp transistor in the on-state. This embodiment can also be described as a split IGBT in parallel with the Cascode device wherein the MOSFET component of the IGBT is one and the same as the MOSFET component of the Cascode device. Preferably the MOSFET is a stand-alone component made in silicon or silicon-carbide technology and the high voltage PNP transistor could be made in silicon or silicon-carbide technology. The high voltage PNP transistor could have a vertical configuration with a wide n base and a relatively narrow p collector or a relatively narrow n base and a relatively wide p collector. The high voltage PNP transistor could have a breakdown voltage similar or slightly smaller than that of the high voltage depletion mode HEMT. The MOSFET could have a voltage blocking much lower than those of the high voltage depletion mode HEMT or the high voltage PNP transistor.

Alternatively, the MOSFET could also be incorporated in the IGBT itself (using the same layers as the MOSFET component of the IGBT) but this would lead to a more complex design for the IGBT.

The high voltage depletion mode HEMT may comprise a gate formed of p+ islands.

According to a fifth aspect of the disclosure, the Cascode is replaced with a high voltage depletion mode HEMT based on p+ islands in series with a MOSFET (as described in patent U.S. Pat. No. 11,081,578). The two series devices are further placed in parallel with the pnp transistor.

The gate of the MOSFET could be directly connected or indirectly connected (through a slew-rate control structure) to the control terminal.

The gate of the p+ islands depletion mode HEMT could be connected through an interface to the control terminal. The interface could be the same as the one described in the first aspect in this disclosure. The role of such interface is to adapt the driving voltage of the control terminal to that suitable and allowable for the p+ islands depletion mode GaN HEMT. The interface may contain other clamping circuits, sensing and protection functions, pull-down devices to ensure a fast and safe turn-off, to enhance immunity against dV/dt and to absorb any transient voltage peaks on the gate. Other sensing and protection functions could also be incorporated.

Alternatively, the high voltage HEMT source terminal and the transistor device first terminal may be operatively connected to the first main terminal through a passive, and/or inductive, component each. This provides a way to modulate the operation of the combined switch as the inductive component would enable to introduce lead/lag in the operation of the two switches so that at times only one switch may be operating within the combined switch. Based on the load conditions, the GaN HEMT may be operated at light load (beneficial low capacitance when the switching loss smaller) through soft switching, and the IGBT or both the IGBT and HEMT may be operated at high load by using hard switching modulation. Current sensing features of GaN HEMT can help to monitor the current and identify the load conditions. These can be communicated to the external driver to enable the appropriate switching between devices based on the load conditions using the energy storing/balancing capabilities of the inductors. The inductors may be coupled inductors or detached inductors.

For example, the high voltage HEMT source terminal may be operatively connected to the first main terminal via a first inductive component, the first inductive component being operable to produce a first temporal lag between the first main terminal and the high voltage HEMT source terminal. The transistor device first terminal may be operatively connected to the first main terminal via a second inductive component, the second inductive component being operable to produce a second temporal lag between the first main terminal and the transistor device first terminal.

The combined switch can switch faster than an IGBT or a first transistor device alone.

The turn-on of the combined switch could be faster than that of an IGBT alone as the internal input capacitance of the high voltage HEMT is very small compared to the input capacitance of the IGBT and therefore it could be charged quickly. During the turn-on the GAN HEMT can take higher current than during the on-state or steady state (as much as the saturation current) until the IGBT turns-on fully and the current is redistributed (part of the current from the GaN HEMT would be redistributed in the IGBT). As a result, the turn-on losses in a combined switch may be smaller than in an IGBT or a first transistor alone.

The high voltage GaN HEMT (or when taken together the high voltage GaN HEMT and the interface) may have a smaller threshold voltage than that of the first switch (e.g. IGBT), so that the high voltage GaN HEMT turn-on before the first switch (e.g. IGBT) turns on.

The turn-off the combined switch could be faster than that of an IGBT alone as the GAN HEMT is a unipolar device and there is no excess charge (i.e. plasma) present in the GaN HEMT. Moreover during the turn-off the current may redistribute compared to the on-state or steady-state. Thus a larger proportion of the current may be switched off by the high voltage GaN HEMT, minimizing the tail of the IGBT component in the combined switch. As a result the turn-off tail and turn-off losses can be smaller in a combined switch than an IGBT alone.

The Combined switch takes advantage of the superior characteristics of the vertical switch (such as IGBTs/or vertical MOSFETs) such as high current capability in medium to full load conditions and good on-state characteristics at high temperature at and superior performance of GaN HEMTs in light load conditions and transient commutation (turn-on and turn-off) to enable the combined device to operate more efficiently in a range of high power applications such as traction inverters and a variety of motor control applications.

The vertical switch and the lateral GaN HEMT could be co-packaged to form a single switch from an external view (similar to System in Package—SIP). This would reduce the parasitics between the corresponding terminals of the two components (high voltage HEMT and vertical switch) and provide a more compact and cost-effective solution. Metal packages or plastic or ceramic type packages could be used, A side by side technique could be employed wherein the GaN Chip and the vertical switch are placed next to each other within the same package and separated by a distance (for example by employing split paddles). The package may contain a common lead frame. Moulding compound may be placed above both components and the heatsink or a metal thermal plate can be common to the components with an isolation layer may be provided between the high voltage terminals and the metal thermal plate if required. Specific terminals of the GaN chip could be connected via internal pads and bond wires to specific terminals of the first switch, or indirectly connected via the package pins. Alternatively, a stack-die or 3D packaging technique could be used. The GaN chip could be placed or soldered or attached onto the IGBT die such that the substrate of the GaN chip could be in physical contact (via soldering or die attach) to the source metallization of the first switch. Alternatively, flip chip techniques with solder balls, or embedded PCB solutions could be used to house the combined switch.

Multiple combined switches could be placed in parallel in modules or within one or multiple embedded PCBs or high conductivity insulating substrates to increase the power (or current) rating.

For example, a semiconductor switch according to the present disclosure may be disposed in a package to form a singular switch. For example, the package may be such that the singular switch is controllable as a single switch (i.e. the high voltage HEMT and the transistor device may perform together as a single switch).

In some cases, a combined semiconductor switch as described herein may comprise devices having different switching speeds. For example, for different power levels, different switching patterns and varying switching speeds should be applied to achieve the best performance without overstressing either device.

If two devices (e.g. IGBT and GaN HEMT) are switched using a same gate driver (i.e. the same driving signal) without additional control, one or more of the following problems may occur:
Turn-on: As the GaN switch is a faster device, it will turn on fast and take all the current, while the slower IGBT will turn-on slowly. This is ideal for low-load situations where the GaN is capable to carry all the current. The small turn-on losses of the GaN will lead to small overall turn-on losses. However, this can be dangerous at high load where the current is high and could potentially damage the GaN device.
Turn-off: The fast GaN will turn off fast and the IGBT will take on all the current and turn off on its own. This may not be ideal for two reasons. Firstly, IGBT turn-off losses are higher. Therefore, in this setup, even at small loads, the high IGBT losses will make the system losses poor. Secondly, the current may suddenly swap from the GaN to the IGBT. This will lead to a considerable di/dt in the IGBT path which, in turn, can lead to inductive over-voltage effects on the terminals of the IGBT.

FIG. 33 illustrates switching patterns for a combined GaN and IGBT switch with two separate gate signals.

The right-most pattern (4) of FIG. 33 illustrates a low-load condition where the GaN device alone is switched so that the combined switch benefits from the superior (lower) switching losses.

As the load increases, as shown in pattern (3) of FIG. 33, the IGBT is switched ON to help with the conduction. It will be understood that, in pattern (3), the IGBT only partially turns off. With the GaN device conducting (and the VDS still low), the plasma in the IGBT remains and is swept out when the GaN device turns OFF (and the voltage rises), leading to additional losses.

At even higher load, at pattern (2) of FIG. 33, the IGBT turns on before the GaN device, despite the non-favorable turn-on losses, to prevent the GaN device from being ON alone, as the higher current could otherwise damage the GaN device.

Pattern (1) of FIG. 33 illustrates the highest load condition. Here, the IGBT switches alone, because switching the GaN device while the IGBT is ON would cause current redistribution and di/dt on the IGBT.

Therefore, it may be desirable to provide a control mechanism that can modulate the switching patterns and switching speeds of the two switches based on the operating conditions.

In some examples described herein, optimized switching performance of a high voltage HEMT (e.g. lateral and/or GaN HEMT) and a high voltage (e.g. vertical) transistor device combined in a semiconductor switch may be achieved under various load conditions using a single gate input. A single interface circuit, or control circuit, may be incorporated in the same package a the combined switch so that externally the combined switch is driven by only a single gate.

Described herein is a semiconductor switch comprising a first main terminal, a second main terminal, and a control terminal, the semiconductor switch comprising:
a high voltage HEMT, the high voltage HEMT comprising a high voltage HEMT source terminal, a high voltage HEMT drain terminal, and a high voltage HEMT gate terminal;
a control circuit; and
a high voltage transistor device, the high voltage transistor device comprising a transistor
device first terminal, a transistor device second terminal, and a transistor device gate terminal;
wherein the high voltage HEMT source terminal and the transistor device first terminal are operatively connected to the first main terminal;
wherein the high voltage HEMT drain terminal and the transistor device second terminal are operatively connected to the second main terminal; and
wherein the high voltage HEMT gate terminal and the transistor device gate terminal are operatively connected to the control terminal via the control circuit.

The control circuit may be configurable to select a switching pattern of the semiconductor switch based on a load condition of the semiconductor switch.

The control circuit may be configured such that the high voltage HEMT terminal and the transistor device gate terminal are independently operable.

The control circuit may be configured to detect the load condition. For example, the control circuit may be configured to detect the load condition by measuring one or more of the following:
a gate voltage of the high voltage HEMT;
a gate voltage of the high voltage transistor device;
a current through the high voltage HEMT;
a current through the high voltage transistor device; and
a drain to source voltage of the high voltage HEMT.

In some examples, the control circuit may be configured to receive the load condition from an external source.

In some examples, the control circuit is configured to receive the load condition as an analog signal.

In some examples, the control circuit is configured to modulate gate charge and/or discharge speed and/or timing for the high voltage HEMT and/or the high voltage transistor device.

In some examples, the control circuit comprises a first low voltage auxiliary HEMT, the first low voltage auxiliary HEMT comprising a first auxiliary HEMT source terminal, a first auxiliary HEMT drain terminal, and a first auxiliary HEMT gate terminal. The first auxiliary HEMT source terminal may be operatively connected to the high voltage HEMT gate terminal. The first auxiliary HEMT drain terminal may be operatively connected to the control terminal. The control circuit may be configured such that modulation of the gate charge speed and timing for the high voltage HEMT is controllable via the first auxiliary HEMT gate terminal.

The control circuit may further comprise an adjustable current source operatively connected to the first auxiliary HEMT gate terminal. The adjustable current source may be configured to control a current feeding the first auxiliary HEMT gate terminal.

The control circuit may further comprise a second low voltage auxiliary HEMT, the second low voltage auxiliary HEMT comprising a second auxiliary HEMT source terminal, a second auxiliary HEMT drain terminal, and a second auxiliary HEMT gate terminal. The control circuit may be configured such that modulation of the gate charge speed and timing for the high voltage HEMT is additionally controllable via the second auxiliary HEMT gate terminal.

The first auxiliary HEMT gate terminal and the second auxiliary HEMT gate terminal may be independently operable.

Preferably, a switching speed of the second low voltage auxiliary HEMT is lower than a switching speed of the first low voltage auxiliary HEMT.

In some examples, the control circuit is configured to detect the load condition by: measuring a gate voltage of the high voltage transistor device, and comparing the gate voltage with a reference voltage.

In some examples, the control circuit is configured to measure a gate voltage of the high voltage transistor device, and to delay a turn-off of the high voltage HEMT until the gate voltage of the high voltage transistor device falls below a threshold voltage level.

In some examples, the control circuit is part of an interface circuit monolithically integrated with the high voltage HEMT. In some examples, the interface circuit is a III-nitride interface circuit.

It will be understood that, in general, the control circuit described herein (which may be part of an interface circuit as described herein) may be implemented independently of the high voltage HEMT and the high voltage transistor device (e.g. on a separate die or chip), or may be present on a same die or chip (e.g. III-nitride die or chip) as e.g. the high voltage HEMT.

### BRIEF DESCRIPTION OF THE DRAWINGS

The present invention will now be described by way of example with reference to the following drawings:

FIG. 1 illustrates a prior art example of an IGBT in parallel with a silicon carbide MOSFET, reproduced from M. Rahimo, IEEE TRANSACTIONS ON POWER ELECTRONICS, VOL. 30, NO. 9, SEPTEMBER 2015;

FIG. 2 illustrates a parallel combination between a discrete GaN HEMT and an IGBT;

FIG. 3 illustrates a prior art solution for paralleling IGBTs with a GaN HEMT, reproduced from L. Molnar, 2018 IEEE 24th International Symposium for Design and Technology in Electronic Packaging (SIITME), 2018;

FIG. 4 illustrates an example of a semiconductor switch according to the present disclosure;

FIG. 5 illustrates an example of a semiconductor switch according to the present disclosure in which the transistor device gate terminal is operatively connected to an output of the interface circuit;

FIG. 6 illustrates an example of a semiconductor switch featuring a lateral GaN HEMT, an auxiliary low voltage HEMT and a high voltage IGBT placed in parallel with the lateral high voltage GaN HEMT according to the present disclosure;

FIG. 7 illustrates an example of a semiconductor switch featuring a lateral GaN HEMT, an auxiliary low voltage HEMT, a pull down device and a high voltage IGBT placed in parallel with the lateral high voltage GaN HEMT, according to the present disclosure;

FIG. 8 illustrates an example of a semiconductor switch wherein the interface circuit comprises an auxiliary low voltage HEMT and a pull down device connected to the gate of a GaN HEMT;

FIG. 9 illustrates the schematic shapes of on-state output I-V characteristics of the high voltage lateral GaN HEMT and the vertical IGBT at room and high temperatures;

FIG. 10 illustrates the schematic shapes of output on-state I-V characteristics of the combined GaN HEMT and IGBT switch according to the present disclosure;

FIG. 11 illustrates the schematic shapes of blocking I-V characteristics of the IGBT and high voltage lateral GaN HEMT at room temperature and high temperature;

FIG. 12 illustrates schematic shapes of blocking I-V characteristics of the semiconductor switch at room temperature and high temperature;

FIG. 13 illustrates an example of a semiconductor switch featuring a lateral high voltage GaN HEMT, an auxiliary low voltage HEMT, and a high voltage SiC MOSFET (or superjunction) in parallel with the lateral high voltage GaN HEMT, according to the present disclosure;

FIG. 14 illustrates a semiconductor switch according to the present disclosure featuring a lateral GaN HEMT, an auxiliary low voltage HEMT, a pull down device and a high voltage IGBT placed in parallel with the lateral high voltage GaN HEMT;

FIG. 15 illustrates a semiconductor switch according to the present disclosure featuring a lateral GaN HEMT, an auxiliary low voltage HEMT, a pull down device and a high voltage IGBT placed in parallel with the lateral high voltage GaN HEMT;

FIG. 16 illustrates a semiconductor switch comprising an additional start-up circuit;

FIG. 17 illustrates a semiconductor switch in which auxiliary HEMT is embedded in a sensing and protection circuit block, which is monolithically integrated with a GaN HEMT;

FIG. 18 illustrates an example of a semiconductor switch according to the present disclosure in which a high voltage HEMT is part of a power integrated circuit;

FIG. 19 illustrates an example of a semiconductor switch comprising slew rate control circuits;

FIG. 20 illustrates an example of a semiconductor switch comprising multiple high voltage HEMTs in parallel with a high voltage transistor device;

FIG. 21 illustrates an example of a semiconductor switch comprising two power integrated circuits, each comprising a high voltage HEMT, in parallel with a high voltage transistor device;

FIG. 22 illustrates an example of a semiconductor switch comprising multiple high voltage HEMTs;

FIG. 23 illustrates an example of a semiconductor switch comprising a silicon companion chip, or integrated circuit;

FIG. 24 illustrates a schematic cross-section representation and connections between a lateral high voltage HEMT, an auxiliary HEMT, and a trench IGBT;

FIG. 25 illustrates a schematic equivalent circuit representation and connections between a lateral high voltage HEMT, an auxiliary HEMT, and an IGBT;

FIG. 26 illustrates a semiconductor switch comprising an IGBT and a GaN Power IC, further comprising a high voltage GaN HEMT and an interface which has at least one connection to the control terminal and at least one connection to the internal gate of the high voltage GaN HEMT;

FIG. 27 illustrates a semiconductor switch according to the third aspect of this invention and based on a Cascode HEMT in parallel with an IGBT;

FIG. 28 illustrates a semiconductor switch according to a fourth aspect of this invention, comprising a depletion MODE HEMT, a MOSFET and a PNP transistor;

FIG. 29 illustrates a semiconductor switch according to a fifth aspect of this invention, comprising a depletion MODE HEMT with p+islands, an interface between a control terminal and the gate terminal of the depletion mode HEMT with p+islands, a MOSFET and a PNP transistor;

FIG. 30 illustrates an example of a voltage limiter;

FIG. 31 illustrates an additional example of a voltage limiter;

FIG. 32 illustrates an additional example of a voltage limiter which comprises a current source;

FIG. 33 illustrates switching patterns for a combined GaN and IGBT switch with two separate gate signals;

FIG. 34 illustrates an example of a semiconductor switch comprising a control circuit;

FIG. 35 illustrates an example of a (GaN) HEMT turn-ON, relative to an IGBT turn-ON, with and without slowing down of the HEMT turn-ON;

FIG. 36 illustrates an example of a turn-on adjustment circuit comprising two auxiliary HEMTs;

FIG. 37 illustrates an example of a turn-on adjustment circuit comprising an adjustable current source;

FIG. 38A illustrates an example implementation for adjusting the turn-on speed of the high voltage HEMT, in which a sense transistor acts on a current source to an auxiliary HEMT;

FIG. 38B illustrates an example implementation for adjusting the turn-on speed of the high voltage HEMT, in which a sense transistor increases a pull-down from a gate of an auxiliary HEMT;

FIG. 39 illustrates how the HEMT turn-on delay is triggered when the transistor device gate voltage approaches VDD;

FIG. 40 illustrates an example implementation in which a load condition is detected by measuring a gate voltage of the high voltage transistor device, and comparing the gate voltage with a reference voltage;

FIG. 41 illustrates an exemplary circuit for measuring the transistor device gate voltage during turn-off; and

FIG. 42 illustrates an exemplary waveform in which the HEMT is kept ON while the transistor device gate voltage is reducing.

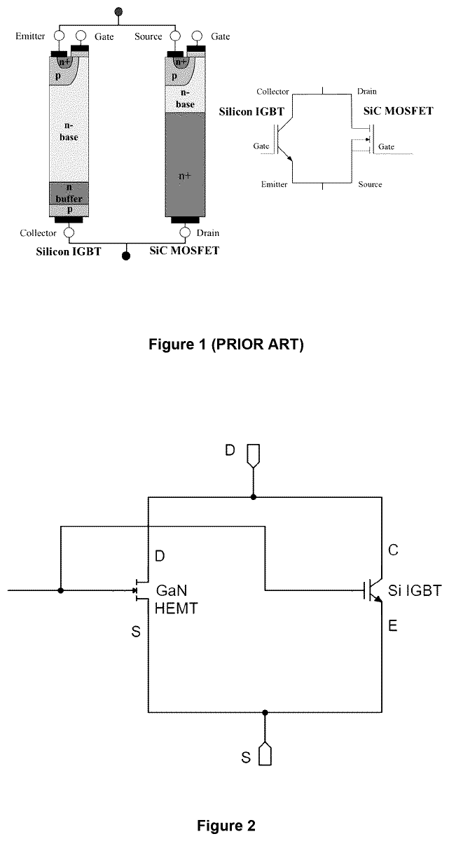

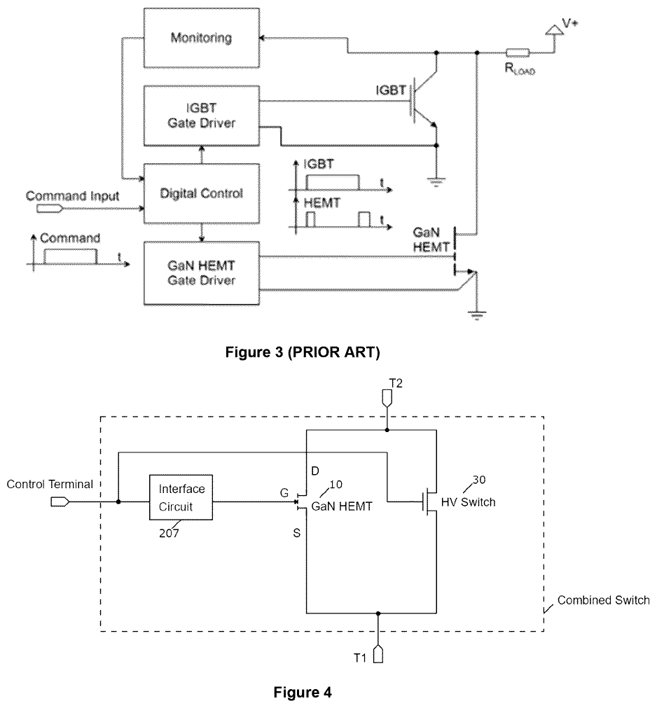

### DETAILED DESCRIPTION

FIG. 4 illustrates a combined switch according to the first aspect of the present disclosure, featuring a lateral GaN HEMT (10), an interface circuit (207) and a high voltage transistor (30). The interface circuit 207 is placed in front of the gate of the lateral GaN HEMT to adapt the driving voltage of the control terminal to that suitable and allowable for the GaN HEMT. This interface could be preferably monolithically integrated with the power HEMT for providing lower parasitics, ease of manufacturing and fast reaction time. Alternatively, this interface could be part of a separate chip (such as a silicon companion chip, or a driver chip). The interface circuit may additionally include clamping circuits, sensing and protection functions, pull-down devices to ensure a fast and safe turn-off, to enhance immunity against dV/dt and to absorb any transient voltage peaks on the gate.

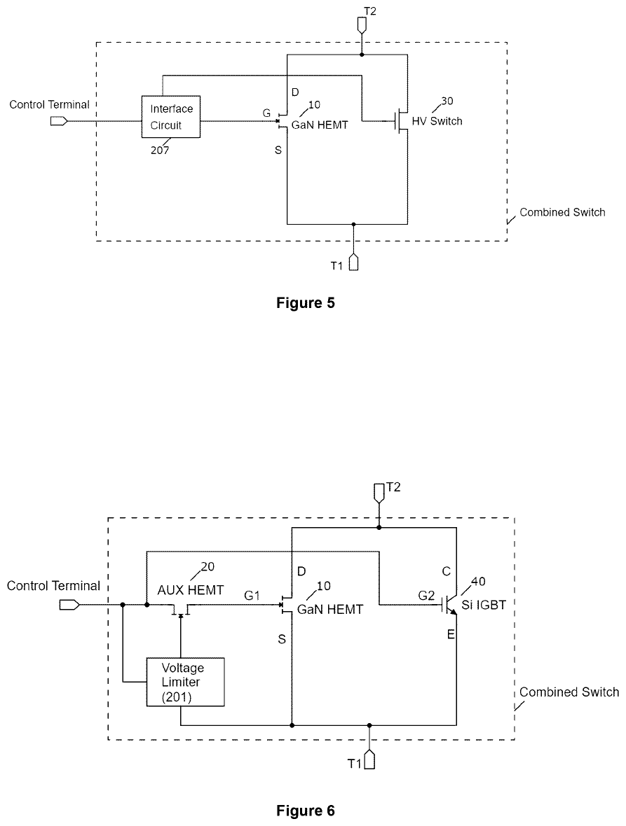

FIG. 5 illustrates an example of the second aspect of the present disclosure, featuring the high voltage transistor (30) to be connected to another output of the interface circuit. The interface circuit can provide functionality of clamping, voltage limiting, sensing and protection and other control functions for the high voltage transistor (30).

As shown in FIG. 6, the interface circuit may additionally comprise a voltage limiter 201. The voltage limiter may be a circuit block which can limit (or clamp) the maximum voltage at the gate of the auxiliary low voltage HEMT. Through this manner of operation the voltage limiter may overall act to provide a limit on the maximum voltage on the gate terminal of the GaN HEMT. In operation, the voltage applied to the control terminal may be divided between a voltage drop between the drain and source terminal of the aux HEMT (20) and a voltage drop between the gate and source terminal of the GaN HEMT (10). The auxiliary HEMT and the voltage limiter may be monolithically integrated with the GaN HEMT.

FIG. 6 illustrates an example of a combined switch featuring a lateral GaN HEMT (10) placed in parallel with a high voltage IGBT (40) and an example of the interface circuit comprising, an auxiliary low voltage HEMT (20) and a voltage limiter (201). The voltage limiter may be a circuit block which can limit (or clamp) the maximum voltage at the gate of the auxiliary low voltage HEMT. Through this manner of operation the voltage limiter may overall act to provide a limit on the maximum voltage on the gate terminal of the GaN HEMT. In operation, the voltage applied to the control terminal may be divided between a voltage drop between the drain and source terminal of the aux HEMT (20) and a voltage drop between the gate and source terminal of the GaN HEMT (10). The auxiliary HEMT and the voltage limiter may be monolithically integrated with the GaN HEMT.

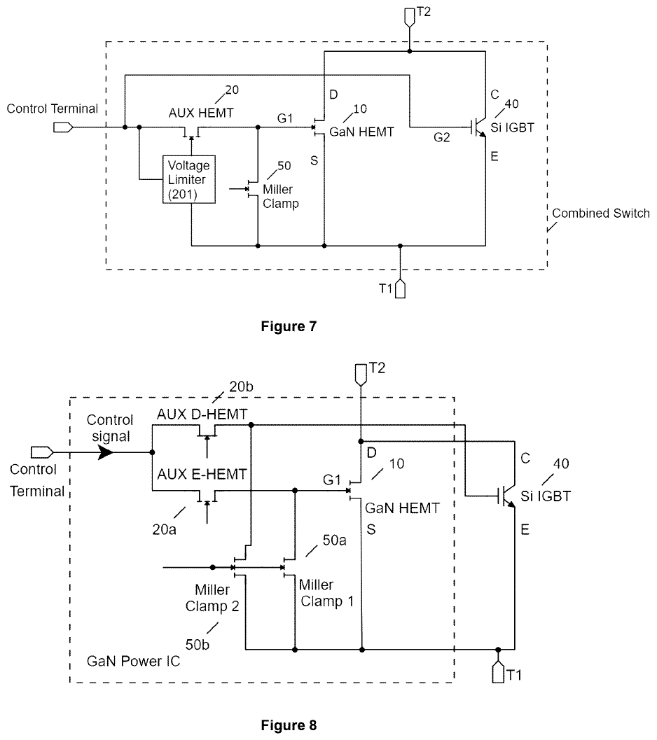

FIG. 7 illustrates another example of a combined switch according to the present disclosure, featuring a lateral GaN HEMT (10), an auxiliary low voltage HEMT (20), a pull down device (Miller clamp, 50) and a high voltage IGBT (40) placed in parallel with the lateral high voltage GaN HEMT (20). The driving circuit for the Miller Clamp (50) is not shown here. For simplicity the Miller clamp may be an active device, for example it may switch according to a signal applied to the control terminal. The signal to the gate of the Miller clamp may be adjusted in relation to the signal at the control terminal for example it may inverted and/or level shifted. The Miller clamp may be monolithically integrated with the GaN HEMT (10), aux HEMT (20) and Voltage limiter (201).

FIG. 8 illustrates an example of the second aspect of the present disclosure. The interface circuit comprises an auxiliary low voltage HEMT (20a) and a pull down device (Miller clamp, 50a) connected to the gate of the GaN HEMT (10) and an additional auxiliary low voltage HEMT (20b) and an additional pull down device (Miller clamp, 50b) connected between the control terminal and the gate of the high voltage IGBT (40). The additional low voltage HEMT (20b) and the additional pull down device (Miller clamp, 50b) enable on-chip regulation or pull-down of the gate voltage of the IGBT. The driving/control circuits of the auxiliary HEMTs and Miller clamps are not shown here for simplicity.

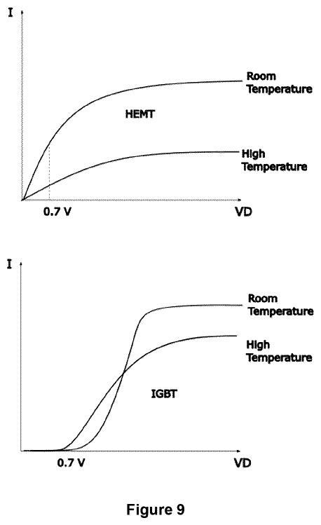

FIG. 9 illustrates the schematic shapes of on-state output I-V characteristics of the high voltage lateral GaN HEMT and the vertical IGBT at room and high temperatures. Note that the HEMT has a linear shape of the characteristics at low currents, while the IGBT does not have any current until 0.7 V and growing super-linearly initially and linearly after 0.7 V (followed by saturation). Note that the HEMT has a severe drop in the current (increased on-state resistance) at high temperatures.

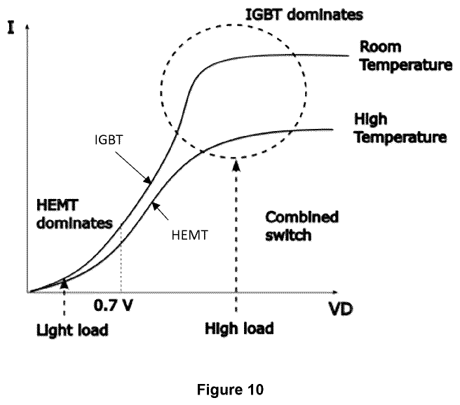

FIG. 10 illustrates the schematic shapes of output on-state I-V characteristics of the combined GaN HEMT and IGBT switch according to the present disclosure. Note that the HEMT current dominates at lower currents/lower on-state voltage drops (below 0.7V)—low load, while the IGBT currents dominates at higher currents (higher on-state voltage drops). At high temperatures, the IGBT compensates the loss in the current of the HEMT. The two parallel devices offer a complementary behavior with improved performance than either the IGBT or the GaN HEMT.

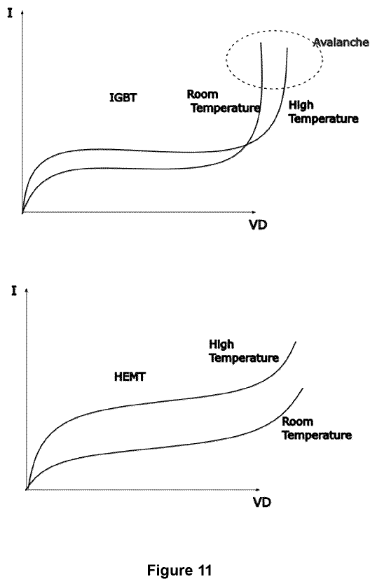

FIG. 11 illustrates the schematic shapes of blocking I-V characteristics of the IGBT and high voltage lateral GaN HEMT at room temperature and high temperature. Note that in both the IGBT and the GaN HEMT the higher the temperature the higher the leakage.

Note that the IGBT breaks via avalanche and typically the avalanche voltage increases with temperature.

Note that lateral GaN HEMT typically break via an increase in the leakage current (typically between the substrate terminal and the drain terminal).

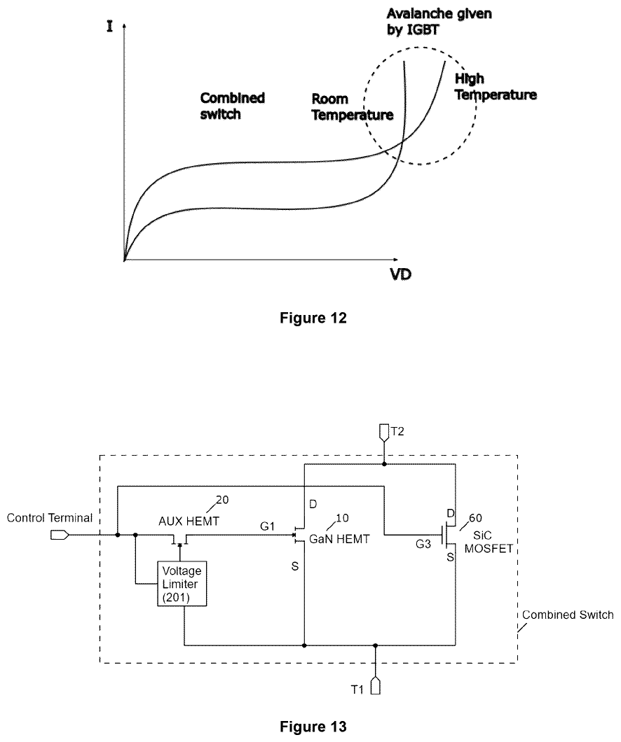

FIG. 12 illustrates schematic shapes of blocking I-V characteristics of the combined switch at room temperature and high temperature. Note that the IGBT mainly dictates the blocking characteristics and the IGBT clamps the voltage during its avalanche. The avalanche capability of the combined switch is provided by the avalanche capability of the IGBT. The avalanche capability of the combined switch may allow the design of a more competitive GaN HEMT. As the maximum voltage across the combined switch can be limited by the avalanche voltage of the IGBT, there may be a reduced need to over-design the breakdown voltage of the GaN HEMT in order to deal with drain-to-source voltage overshoots in operation.

FIG. 13 illustrates a combined switch according to another aspect of the present disclosure, featuring a lateral high voltage GaN HEMT (10), an auxiliary low voltage HEMT (20), and a high voltage SiC MOSFET (or superjunction MOSFET) (60) in parallel with the lateral high voltage GaN HEMT (10).

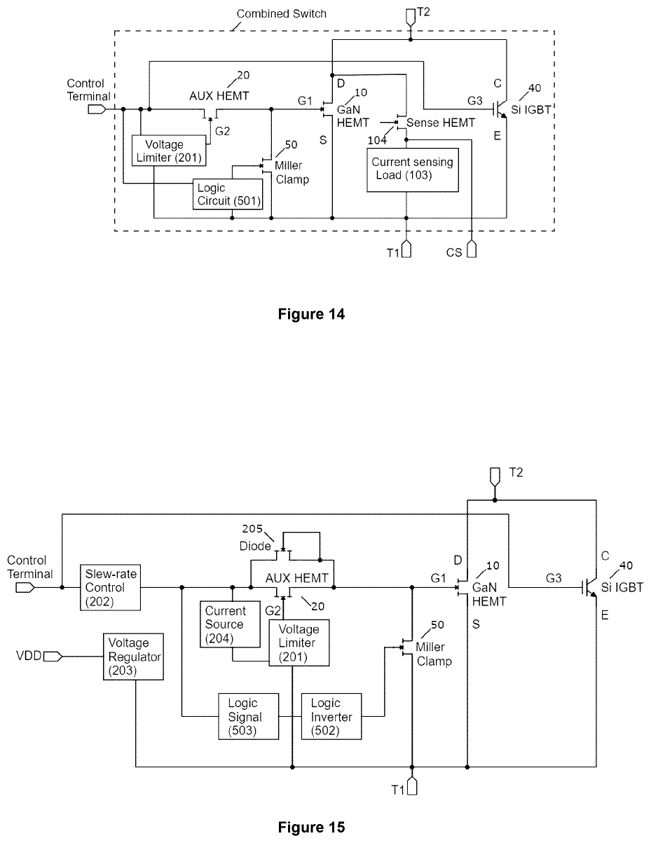

FIG. 14 illustrates a combined switch according to the present disclosure featuring a lateral GaN HEMT (10), an auxiliary low voltage HEMT (20), a pull down device (Miller clamp, 50) and a high voltage IGBT (40) placed in parallel with the lateral high voltage GaN HEMT (10). A current sense HEMT (104) is monolithically integrated within the GaN chip (alongside the other GaN devices). The current sensing load (resistance) (103) could also be integrated or provided externally. Other circuit blocks such as logic circuits (501) to drive the miller clamp (50) (pull-down transistor) or voltage limiter (201) placed in the gate of the auxiliary HEMT are also monolithically integrated within the GaN chip. The logic circuit can have a connection to the control terminal (external gate) and may comprise an inverter. The voltage limiter can be driven by a current source from the control terminal as shown in FIG. 15. The circuit blocks (50) (501) (20) (201) may be described as being blocks of an overall interface circuit which operates in order to limit the maximum voltage at the gate of the GaN HEMT (for example to 7V) while a higher voltage is applied to the control terminal (for example 20V). The interface circuit is additionally configured to allow a switching signal at the gate of the GaN HEMT when a switching signal is applied to the control terminal. The switching signal may be limited in voltage as described. The interface circuit may also be configured to provide a threshold voltage increase when considering the GaN HEMT and the interface circuit in combination compared to considering the threshold voltage of the GaN HEMT as a discrete device. Through the operation of the interface circuit compatibility between the driving requirements of the GaN HEMT and the IGBT may be ensured such that they may be driven by a control signal from a single gate driver.

In the embodiment of FIG. 15, the voltage limiter (201) is connected between the gate of the auxiliary HEMT (20), the HEMT source terminal and the control terminal (via the current source (204) and slew rate control circuit(202)). This is an additional example of how the voltage limiter may be connected. In this configuration, the voltage limiter can limit (or clamp) the maximum voltage at the gate of the auxiliary low voltage HEMT in relation to the voltage, VDD. FIG. 15 illustrates a combined switch according to the present disclosure featuring a lateral GaN HEMT (10), an auxiliary low voltage HEMT (20), a pull down device (Miller clamp, 50) and a high voltage IGBT (40) placed in parallel with the lateral high voltage GaN HEMT (10). Other circuit blocks such as logic signal (503)/logic inverter (502) circuits to drive the Miller clamp (50) or voltage limiter (201) placed in the gate of the auxiliary HEMT (20) are also monolithically integrated within the GaN chip. A voltage regulator (203), which may regulate an externally applied VDD to a suitable DC voltage to drive the on-chip logic circuits is included. A diode (205) (possibly made of a HEMT with the gate shorted to one of the source/drain terminals) could be placed in parallel with the AUX HEMT (20) to aid the turn-off of the high voltage GaN HEMT (10). The logic circuit (similar to that in FIG. 12) can have a connection to the control terminal and may comprise a logic signal (503) and an inverter (502). The voltage limiter (201) can be driven by a current source (204) from the control terminal. A slew rate control circuit (202) is included to adjust the speed of the turn-on and turn-off of the GAN HEMT. This could be monolithically integrated with the high voltage GaN HEMT or provided externally.

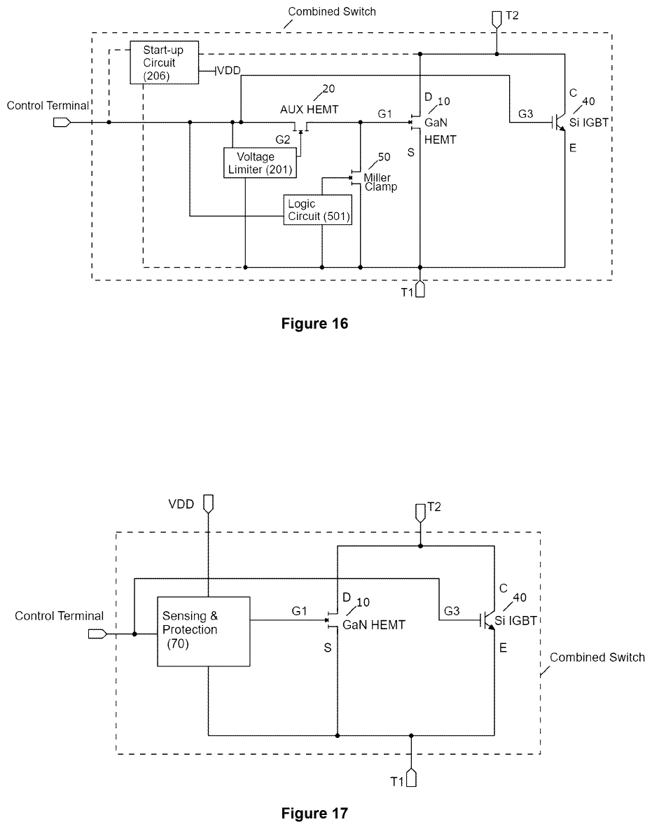

FIG. 16 is similar to FIG. 14 but with an additional start-up circuit (206) which could avoid the need to apply an external VDD voltage for the operation of the combination circuit and the interface circuit blocks. In this embodiment the voltage rail required by the interface circuit blocks may be generated internally through the start-up circuit from either the control terminal or the high voltage terminal (or both).

FIG. 17 illustrates a more generic structure where the Aux HEMT is embedded in the sensing and protection circuit block (70) which is monolithically integrated with the GaN HEMT (10). The Sensing and protection circuit block could comprise various functions such as voltage clamping circuits and Miller clamp devices.

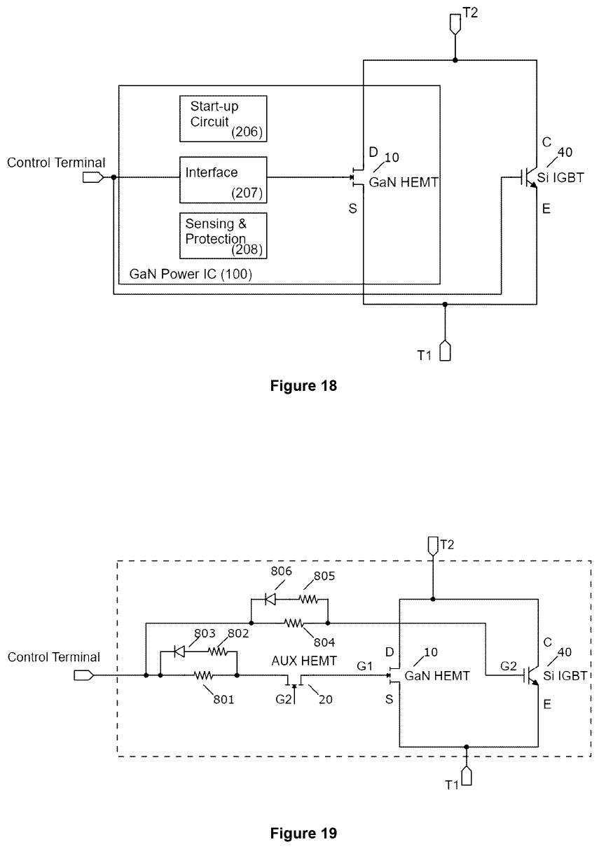

FIG. 18 illustrates another aspect of the first aspect of the present disclosure where the High Voltage GaN HEMT (10) could be part of a GaN Power IC (100). An interface circuit (207) has at least one connection to the control terminal and at least one connection to the internal gate of the high voltage GaN HEMT (10), wherein the interface allows driving voltage compatibility between the high voltage device (40) (e.g. IGBT) and the high voltage GaN HEMT (10). The GaN Power IC (100) may contain other devices/circuits, such as start-up (206) and sensing and protection circuits (208).

FIG. 19 illustrates an example of simple slew rate control circuits that can be provided externally and inserted before the Aux HEMT or in the gate of the IGBT to adjust individually the speed of the two devices. This simple method can also be used for a more balanced (or more desirable) sharing of the current during the transient voltages. Instead of the resistors 801, 804 and resistors 802, 805 with diodes 803, 806, more complex slew rate circuits can be integrated monolithically alongside the high voltage GaN HEMT.

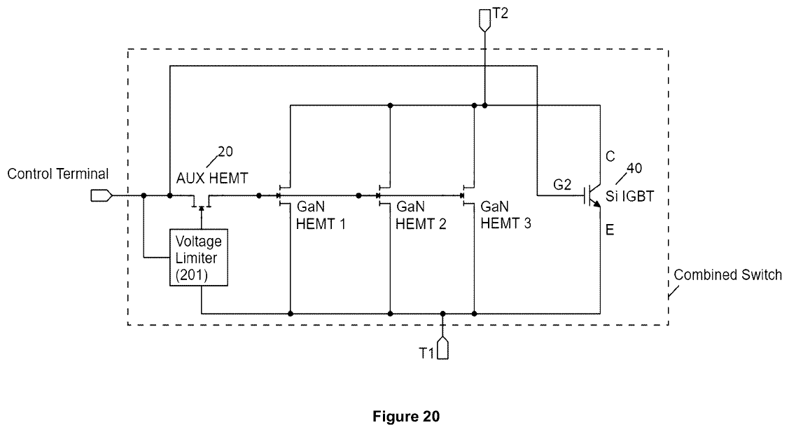

FIG. 20 illustrates an example where multiple high voltage GaN HEMTs can be provided in parallel with the high voltage device (IGBT). One (shown) or multiple Aux HEMTs (not shown) can be connected to the internal gate of the high voltage GaN HEMTs. Multiple parallel IGBTs (not shown) can also be connected to scale up the current capability of the combined switch.

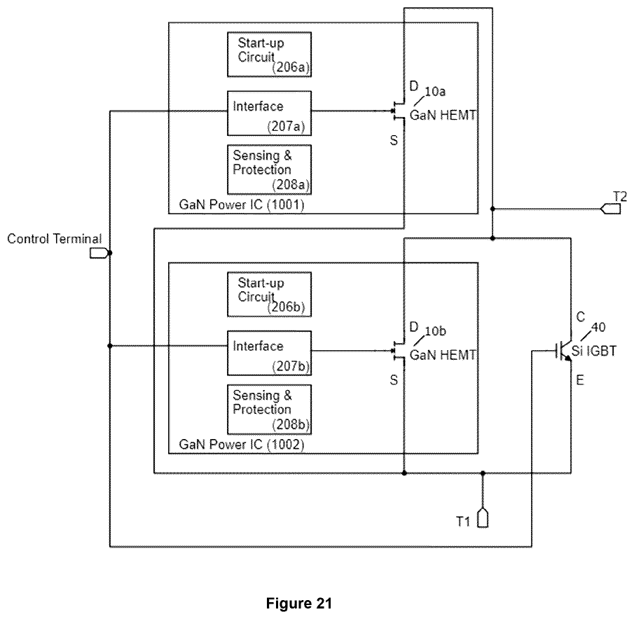

FIG. 21 shows multiple (shown two) Power ICs as were illustrated in FIG. 17. The two Power ICs are connected in parallel. Additionally, the combination of two Power ICs in parallel, can be provided in parallel with the high voltage device (IGBT).

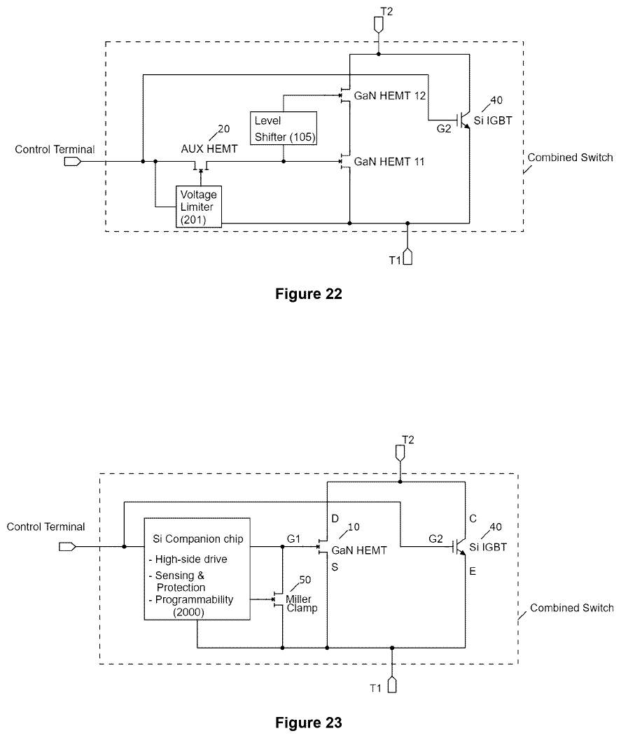

FIG. 22 shows series of multiple high voltage HEMTs (here shown only two) can be provided instead of a single GaN HEMT. This could be a solution if higher blocking voltages (e.g. in excess of 1.2 kV) are needed. A level shifter (105) could be used for the upper GaN HEMT (12). The level shifter could be monolithically integrated with the lower GaN HEMT (11) or provided externally.

FIG. 23 illustrates another embodiment of the present disclosure where a silicon companion chip (2000) can be co-packaged with the Power HEMT (10). The Miller clamp (50) can be monolithically integrated with the GaN HEMT (10). The silicon companion chip can provide an interface allowing a compatible voltage range for driving the GaN HEMT (10) and the IGBT (40). The companion chip (2000) can provide voltage clamping action, slew rate control, high side drive and other sensing and protection features. It can have programmable functions and can be made in mix-signal processes which allow both digital and analogue components to be integrated. A BCD (Bipolar CMOS DMOS) process can be used as an example.

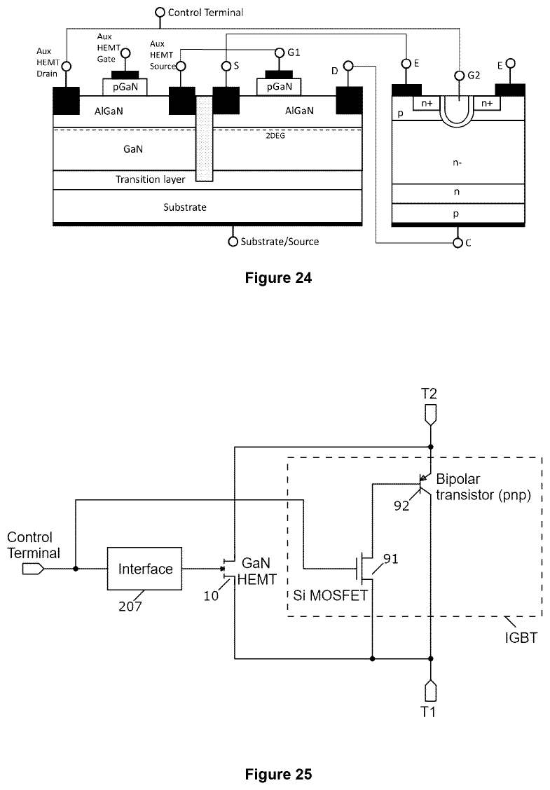

FIG. 24 illustrates a schematic cross-section representation and connections between the lateral high voltage GaN HEMT, the Aux GaN HEMT and a trench IGBT.

FIG. 25 illustrates a schematic representation of the equivalent circuit and connections between the lateral high voltage GaN HEMT (10), an interface circuit (207) comprising the Aux GaN HEMT, and an IGBT. The IGBT is described as a combination between an n-channel MOSFET (91) and a bipolar PNP transistor (92) with the drain of the n-channel MOSFET being connected to the base of the PNP transistor.

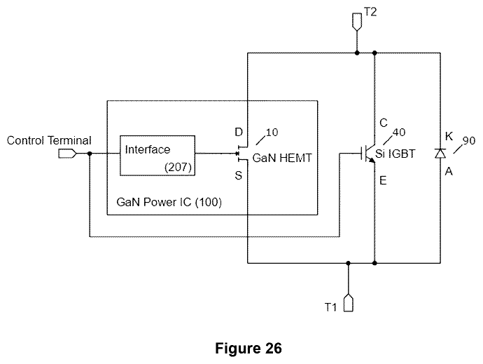

FIG. 26 illustrates a combined switch comprising an IGBT (40) and a GaN Power IC (100) further comprising a high voltage GaN HEMT (10) and an interface (207) which has at least one connection to the control terminal and at least one connection to the internal gate of the high voltage GaN HEMT. An extra high voltage anti-parallel diode (90) is added to aid the reverse conduction. This diode could become in parallel with the existing intrinsic 2DEG reverse conducting diode of the high voltage GaN HEMT. The extra diode could be part of a Reverse Conducting IGBT (RC IGBT) or could be an independent bipolar or Schottky or Schottky-based diode made in silicon or silicon carbide.

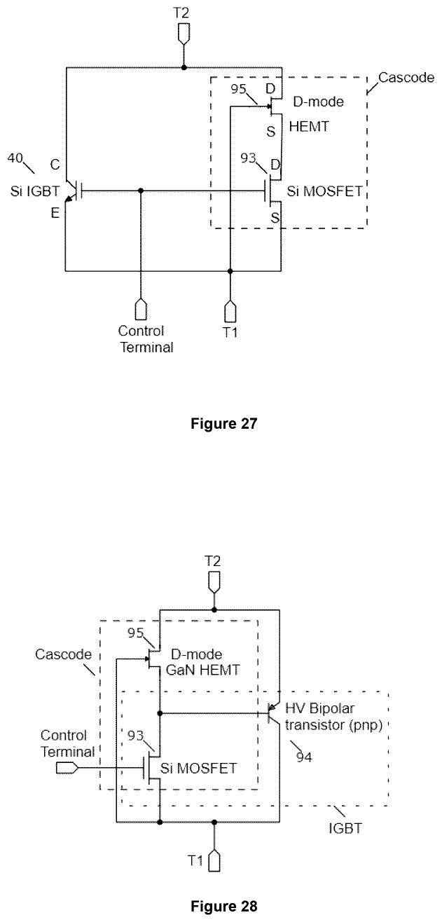

FIG. 27 illustrates a device according to a third aspect of the present disclosure, comprising a Cascode device in parallel with an IGBT. The Cascode device comprises a MOSFET (93) (an n-channel MOSFET made preferably in silicon or silicon carbide technology) in series with a high voltage depletion mode HEMT (95) (made in III-Nitride material). The gate of the depletion mode GaN HEMT is connected to the source of the MOSFET.

FIG. 28 illustrates a device according to a fourth aspect of the present disclosure, comprising a MOSFET (93) (n-channel MOSFET, preferably in silicon or silicon-carbide technology), a high voltage depletion mode HEMT (95) and a PNP transistor (94) (bipolar junction transistor). The drain of the n-channel MOSFET is connected to the base of the high voltage PNP transistor and also to the source of the high voltage depletion mode HEMT.

The n-channel MOSFET is responsible for both (i) enabling a negative gate-source voltage for the depletion HEMT during the blocking mode and (ii) providing the electron current to the base of the pnp transistor in the on-state. Preferably the MOSFET is an n-channel stand-alone component made in silicon or silicon-carbide technology and the high voltage PNP transistor could be made in silicon or silicon-carbide technology. The high voltage PNP transistor could have a vertical configuration with a wide n base and a relatively narrow p collector or a relatively narrow n base and a relatively wide p collector.

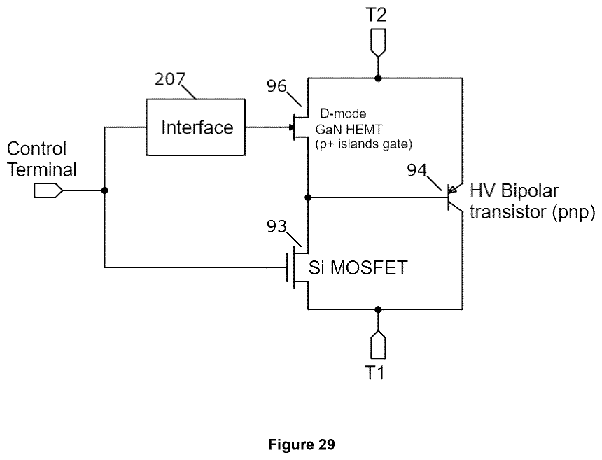

FIG. 29 illustrates a device according to a fifth aspect of the present disclosure. The Cascode device in FIG. 28 is replaced with a high voltage depletion mode HEMT based on p+ islands in series with a MOSFET (as described in U.S. Pat. No. 11,081,578). The two series devices are further placed in parallel with the pnp transistor.

The gate of the p+ islands depletion mode HEMT could be connected through an interface (207) to the control terminal. The interface could be the same as the one described earlier in the first aspect of this disclosure. The role of such interface is to adapt the driving voltage of the control terminal to that suitable and allowable for the p+ islands depletion mode GAN HEMT.

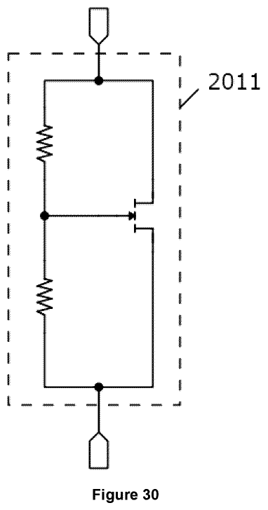

FIG. 30 illustrates an example of a voltage limiter (2011). In this example the voltage limiter comprises an enhancement mode HEMT and two resistors. One terminal of the voltage limiter may be connected to the gate of the auxiliary HEMT and the other terminal may be connected to the source terminal of the GaN HEMT or to a voltage VDD as illustrated in previous examples.

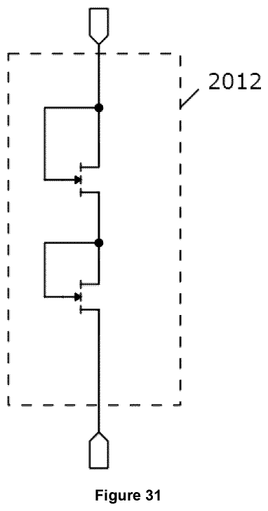

FIG. 31 illustrates an additional example of a voltage limiter (2012). In this example the voltage limiter comprises two enhancement mode HEMTs in series connected in a diode-like manner. A different number of enhancement mode HEMTs in series may be used in other examples depending on the desirable voltage limit of the circuit.

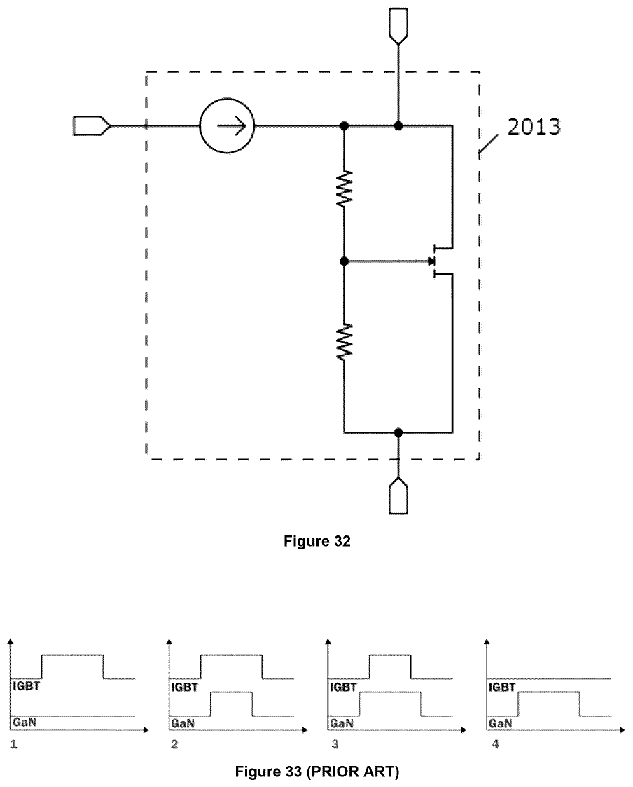

FIG. 32 illustrates an additional example of the voltage limiter (2013), similar to FIG. 30, which also comprises a current source. The current source is useful in setting the voltage limit of the voltage limiter while controlling the power dissipation of the circuit in operation.

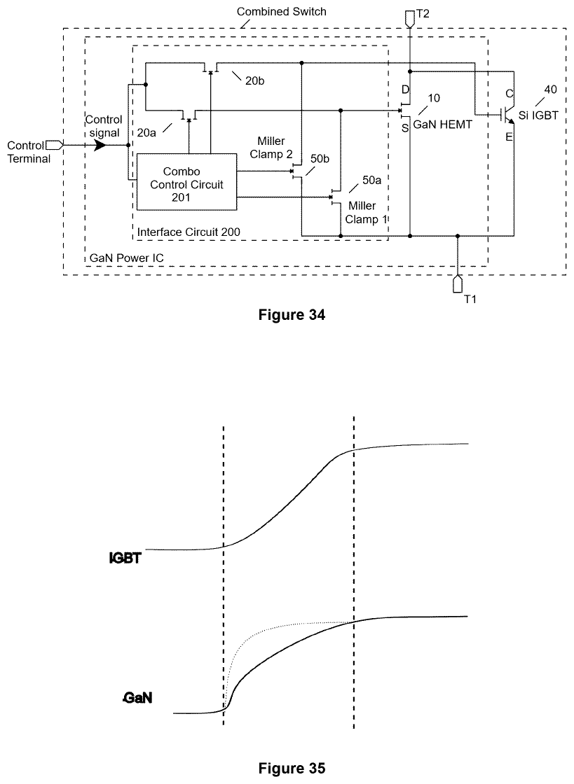

FIG. 34 illustrates an example of a semiconductor switch (combined switch) according to the present disclosure comprising a control circuit (201), which in the illustrated example is part of an interface circuit (200). As described herein, in some examples, the control circuit 201 may be provided separately from the HEMT (e.g. on a separate chip or die), or may be on a same chip or die.

As shown in FIG. 34, the gate driver drives both the high-voltage GaN HEMT and the high voltage transistor device (IGBT) through the interface circuit. The interface circuit comprises an auxiliary low voltage HEMT (20a) and a pull down device (Miller clamp, 50a) connected to the gate of the GaN HEMT (10) and an additional auxiliary low voltage HEMT (20b) and an additional pull down device (Miller clamp, 50b) connected between the control terminal and the gate of the high voltage IGBT (40). The auxiliary low voltage HEMTs (20a, 20b) and the pull down devices (50a, 50b) are connected to a control circuit, also referred to herein as a combo control circuit (201), that is configured to control the operation of these devices.

The respective low voltage HEMT and Miller Clamp of each switch may be incorporated on same interface circuit or on different interface circuits. There interface circuits may be monolithically integrated in the GaN die same as the high voltage HEMT or may be provided on an additional GaN die or may be provided on a separate silicon die as a companion chip.

The Combo Control circuit (201) is configured to adjust the speed and timing of charging and discharging the gates of the high-voltage GaN HEMT and the high voltage transistor device (IGBT).

In some implementations, the combo control circuit (201) may additionally incorporate an internal memory (e.g. 1 bit) or may be provided with external pins to set the behavior based on the desired pattern.

The combined switch may operate in one of the switching patterns as illustrated in FIG. 33, listed below.
1. Switching pattern (4) relates to a low-load condition (for example up to 30% current rating of the GaN device) where the GaN device alone is switched to take advantage of the superior switching losses.
2. Switching pattern (3) relates to increasing load conditions from the lowest-load condition (for example from 30% to 60% current rating of the GaN device), wherein as the load increases the IGBT is switched ON to help with the conduction.
3. Switching pattern (2) relates to higher load conditions (for example from 60% to 90% current rating of the GaN device). In such conditions, the GaN device must not be ON alone because the higher current could damage the GaN device. Therefore, IGBT turns ON before GaN despite the non-favorable turn-on losses.
4. Switching pattern (1) illustrates the highest load condition (for example greater than 90% current rating of the GaN device), where the IGBT alone switches. This avoids a situation where the GaN may also switch while the IGBT is ON as this can cause current redistribution and di/dt on the IGBT.

According to the present disclosure, the interface circuit is configured to detect the load condition and select the desired switching pattern.

In some implementations, the switching pattern selection may be performed at system level, wherein the combined switch would need input pins to enable the change of the switching behavior at system level.

Alternatively and preferably, the switching pattern could be selected inside the combined switch itself. For example, load conditions may be determined by measuring the GaN current and/or VDS voltage.

In some implementations, the combined switch may be configured to have a combination of internal and system-level switching pattern selection. For example, the load current may be provided as an analog signal and the combined switch may decide the switching pattern.

The combo control circuit is configured to implement this switch pattern selection. Different modes of operations will be discussed below.

For example, if the system is operating in highest-load (pattern (1)) or lowest-load conditions (pattern (4)), GaN HEMT or IGBT are not switching, respectively. This may be controlled by keeping respective auxiliary low voltage HEMT (20a or 20b) turned OFF (applying 0V to their gates), respectively. Alternatively, respective Miller Clamps (50a or 50b) of the GaN HEMT or IGBT may be kept ON to ensure that their respective switches are OFF. The turn-ON of the GaN HEMT and IGBT may not need to be adjusted. They will turn-ON as quickly as possible.

If the system is operating in pattern (3), the current in the system can be handled fully by the GaN switch and the GaN switch does not need slowing down (dotted line in FIG. 35). The IGBT switches at its normal speed, which is slow compared to the GaN and therefore leads to a favorable configuration.

In some implementations, the transition between pattern (4) and pattern (3) could happen during the on-time, rather than on the next pulse. A high current detection in GaN would trigger the turn-on of the IGBT.

If the system is operating in pattern (2), the GaN switch needs to be slowed down or delayed in order to reduce the current in the GaN HEMT and not to overstress it.

Various methods of adjusting the turn-on of the switches can be used. Some ways of achieving these turn-on adjustments are discussed below.

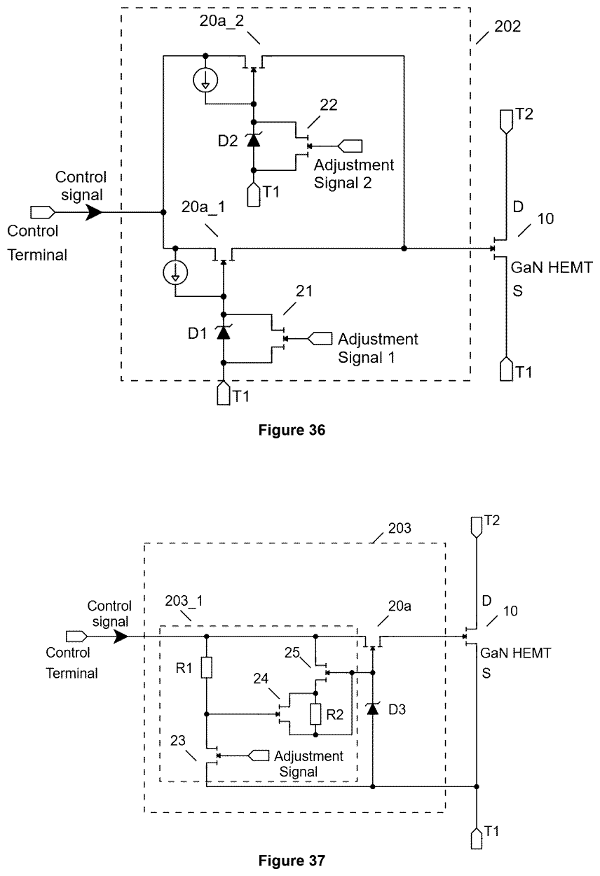

According to one example, the combined switch may comprise a turn-on adjustment circuit 202 for the GaN HEMT incorporating two AUX HEMTs (20a_1 and 20a_2) for driving the GaN HEMT as illustrated in FIG. 36. Both AUX HEMTs (20a_1 and 20a_2) may be provided with respective control transistors whose gates can independently be activated or deactivated through a respective adjustment signal. One AUX HEMT could be faster than the other AUX HEMT. By changing the adjustment signals, three different turn-on speeds for the GaN HEMT could be achieved. The adjustment signals are independent of each other and may be provided by the combo control circuit or externally. The adjustment signals could be analog or digital signals. The turn-on adjustment circuit 202 may be a part of the combo control circuit 201 shown in FIG. 34. In some examples, the turn-on adjustment circuit 202 may be part of an overall interface circuit 200, 207 e.g. of the kind shown in FIG. 5. As described herein, the combo control circuit 201 or interface circuit 200 may be independent of, or part of, a same die or chip as the high voltage (GaN) HEMT. It will be understood that other circuits or components of the interface circuit or combo control circuit such as Miller Clamps etc. are not shown in the figure merely for simplicity. Furthermore, the Zener diodes shown in FIG. 36 and subsequent embodiments are only used for illustration. If the combo control circuit is implemented on a silicon die, Zener diodes may be used. Otherwise any conventional GaN circuit with a similar behavior would be used. In addition, other alternative voltage regulation circuits are also feasible.

According to another example, the combined switch may comprise another turn-on adjustment circuit 203 comprising an adjustable current source 203_1 as illustrated in FIG. 37. The adjustable current source 203_1 may be incorporated to feed the gate of the AUX HEMT 20a. The current of this current source can be adjusted by controlling the gate of the transistor 23 through an adjustment signal. By setting the adjustment signal HIGH, the current feeding the gate of the AUX HEMT 20a is reduced (with a controlled ramp/slew rate). It may be understood that this is just one example of a current source merely for illustration. Other implementations of an adjustable current source are feasible.

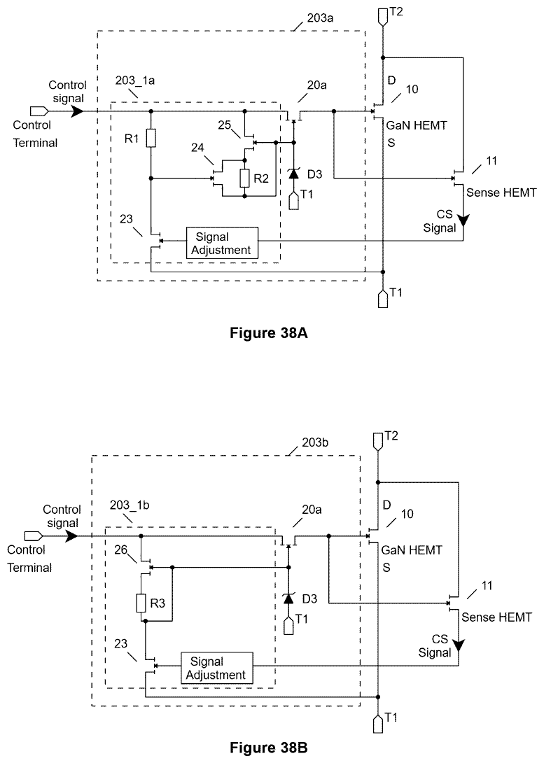

FIGS. 38A and 38B illustrate another method of adjusting the turn-on speed of the GaN HEMT. As disclosed in U.S. Pat. No. 10,818,786B1, the contents of which are hereby incorporated by reference, a current sense transistor (11 in FIGS. 38A and 38B) is generally connected in parallel to a power HEMT to sense the current through the power HEMT. The current sense signal CS is measured during switching. If the current is high, transistor 23 is activated and the turn-on is slowed down. Transistor 23 can act on the current source to the AUX HEMT 20a (FIG. 38A) as illustrated in FIG. 37 or could increase the pull-down from the gate of the AUX HEMT 20a (FIG. 38B). For example, in FIG. 38A, when the current to gate of transistor 23 will be high, the current feeding the gate of the AUX HEMT is reduced through the adjustable current source 203_1a (with a controlled ramp/slew rate). As shown in FIG. 38B, when the current to gate of transistor 23 will be high, transistor 23 will pull down the gate of the AUX HEMT 20a, eventually adjusting the turn-on of the GaN HEMT 10. Additionally or optionally, a signal adjustment block may be configured to provide the functionality of deactivating this adjustment function. Alternatively, the current sense transistor may be replaced by a sense transistor that can measure the drain voltage (VDS) of the GaN HEMT. Therefore, reduction of VDS can be monitored as a result of IGBT turn-on, before the GaN HEMT is controlled to turn-on more.

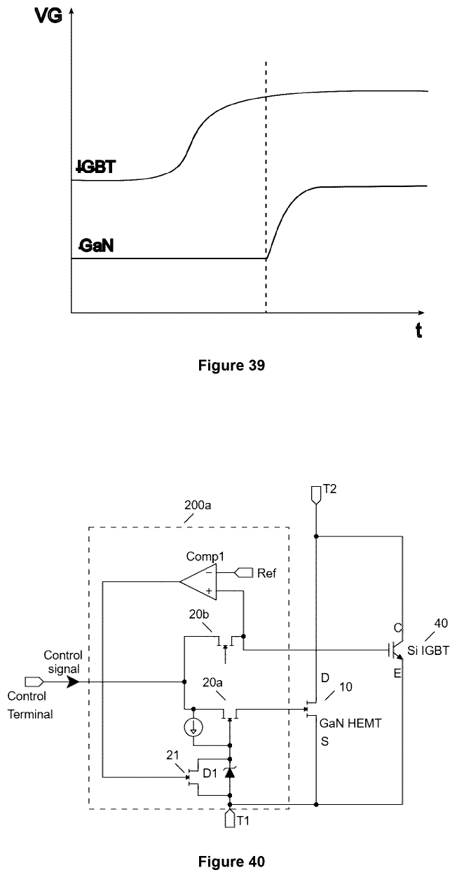

In some implementations, the gate voltage of IGBT may be measured to control the turn-on adjustment of the GaN HEMT. As the gate of IGBT is connected through the interface circuit, the combo control circuit has access to the IGBT gate. FIG. 39 illustrates how the GaN turn-on delay is triggered when the IGBT gate voltage approaches VDD. At this point, the IGBT starts to conduct the current, therefore it would be safe for the GaN HEMT to turn-on. This point of transition to trigger GaN turn-on may be identified by various methods. Some examples are listed below:
Compare the IGBT gate voltage to VDD (e.g. one threshold below VDD);
Compare the IGBT gate voltage to outer gate voltage (control terminal);
Compare the IGBT gate voltage to the gate voltage of the AUX HEMT;
Compare the IGBT gate voltage to an absolute reference (e.g. reference voltage) (e.g. external or generated from VDD).

Any of the above examples can be made temperature dependent to adjust the timing with temperature or adjustable (e.g. with co-packaged resistors or bonding options) for different IGBT types.

FIG. 40 illustrates one example implementation of sensing an IGBT gate voltage and comparing with any one of the references mentioned above to feed to the auxiliary HEMT gate to control the GaN HEMT turn-on. All the sensing and comparison circuits may be incorporated in the combo control circuit and/or the interface circuit (shown as 200a in FIG. 40). It will be understood that additional logic function circuits, filters, level shifters or other signal processing circuits can be added before and after the comparator.

Additionally, various methods of adjusting the turn-off of the switches can be used to ensure optimal operation of the combined switch. Subsequent examples will describe some approaches to achieving these turn-off adjustments. Experimental and theoretical considerations have shown that turn-off adjustment during switching conditions where both the IGBT and the GaN HEMT are ON (switching patterns (2) and (3)) may benefit from one or more of the approaches described herein.

During higher-load conditions when the combined switch is operating in switching pattern (2) as shown in FIG. 33, the GaN HEMT should be turned-off slowly to avoid a fast di/dt in the IGBT that can damage the IGBT. United Kingdom pending patent application number 2513533.6, the contents of which are hereby incorporated by reference, describes a method of slew rate control with the help of the interface circuit. This method or any other slew rate control method can be applied to control the slow turn-off of the GaN HEMT.

During lower-load conditions when the combined switch is operating in switching pattern (3) as shown in FIG. 33, the IGBT continues to have the electron-hole plasma, even after the gate is turned-off. Once the GaN HEMT turns off, the voltage rises and a depletion zone is formed which sweeps out the electron and holes from the IGBT. These charges cause additional switching losses. Therefore, a delay time is beneficial to reduce the losses (up to around 1 μs). However, a delay time would lead to a long effective turn-off delay time (tdoff) and therefore potentially cause issues for the control system.

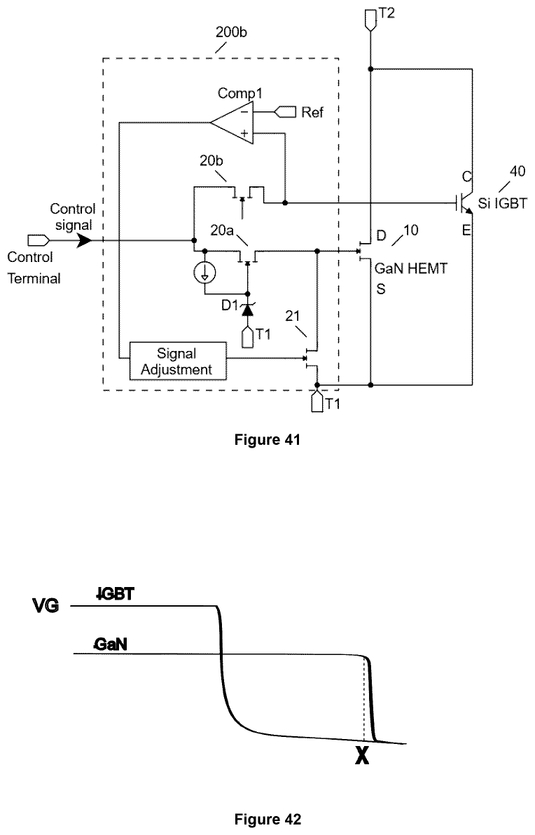

According to the present disclosure, it is suggested to measure the IGBT gate voltage during turn-off for pattern (3). The GaN device is kept ON while the IGBT gate voltage is reducing. Once the IGBT gate voltage reaches below a certain voltage level (trigger point X in FIG. 42), the turn-off of the GaN device is initiated. Optionally, the GaN device turn-off can be further delayed by a fixed or variable time (e.g. depending on temperature or current). FIG. 42 shows an exemplary waveform and FIG. 41 illustrates an exemplary circuit for this function. All the sensing/measuring and comparison circuits may be incorporated in the combo control circuit and/or the interface circuit. It may be understood that additional logic function circuits, delay circuits, filters, level shifters or other signal processing circuits can be added to the turn-off adjustment circuit. In the off-state the input gate signal may be at 0V or at a negative voltage compared to the source of the power device. Negative gate voltage may provide an advantage to the switching losses of the IGBT.

Turn-off adjustment methods described for switching pattern (2) and switching pattern (3) may be combined in the combo control circuit. The main advantage of measuring the IGBT gate voltage is that it lets the IGBT complete the first stages of the turn-off process and only after that the GaN will start to turn-off. This will help to accommodate various load conditions of the IGBT and device-to-device variation of IGBTs.

The combo control circuit is configured for internal pattern selection, to switch between the different adjustment methods as described in earlier examples based on the load conditions. To enable this functionality, different current thresholds may be set inside the combined switch chip. The thresholds would be determined by the ratio of GaN HEMT to IGBT power capacity, so it needs to be programmed at the die level unless the die is provided with external programmable inputs or controls. Any known methods of die-level programming may be used to achieve this such as bonding options, or external resistors to change thresholds, or well as one-time programmable fuses (or non-volatile memory or metal options or other trimming circuits) to activate on the GaN die. One-time programming circuits may also be used to adjust the behavior for various IGBT types or applications.

The incoming current sense signal would be compared to a set level, which would determine the switching mode. There may be hysteresis between rising current and falling current so that the combined switch is not oscillating between modes of operation.

Switching between the modes may preferably be sequential. So, the combined chip may compare the current sense to the next mode switch level based on the operating mode.

It will be appreciated that terms such as “top” and “bottom”, “above” and “below”, “lateral” and “vertical”, and “under” and “over”, “front” and “behind”, “underlying”, etc. may be used in this specification by convention and that no particular physical orientation of the device as a whole is implied.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in the disclosure, whether alone or in any appropriate combination with any other feature disclosed or illustrated herein.

1. A semiconductor switch comprising a first main terminal, a second main terminal, and a control terminal, the semiconductor switch comprising:
a high voltage HEMT, the high voltage HEMT comprising a high voltage HEMT source terminal, a high voltage HEMT drain terminal, and a high voltage HEMT gate terminal;
a control circuit; and
a high voltage transistor device, the high voltage transistor device comprising a transistor device first terminal, a transistor device second terminal, and a transistor device gate terminal;
wherein the high voltage HEMT source terminal and the transistor device first terminal are operatively connected to the first main terminal;
wherein the high voltage HEMT drain terminal and the transistor device second terminal are operatively connected to the second main terminal; and
wherein the high voltage HEMT gate terminal and the transistor device gate terminal are operatively connected to the control terminal via the control circuit;
wherein the control circuit is configurable to modify a switching pattern of the semiconductor switch based on a load condition of the semiconductor switch, wherein modifying the switching pattern of the semiconductor switch comprises modulating gate charge and discharge speed and/or timing for the high voltage HEMT and the high voltage transistor device; and
wherein the control circuit is configured such that the high voltage HEMT terminal and the transistor device gate terminal are independently operable.

2. The semiconductor switch of claim 1, wherein the control circuit is configured to detect the load condition.

3. The semiconductor switch according to claim 2, wherein the control circuit is configured to detect the load condition by measuring one or more of the following:
a gate voltage of the high voltage HEMT;
a gate voltage of the high voltage transistor device;
a current through the high voltage HEMT;
a current through the high voltage transistor device; and
a drain to source voltage of the high voltage HEMT.

4. The semiconductor switch, wherein the control circuit is configured to receive the load condition from an external source.

5. The semiconductor switch according to claim 4, wherein the control circuit is configured to receive the load condition as an analog signal.

6. The semiconductor switch according to claim 1, wherein the control circuit comprises a first low voltage auxiliary HEMT, the first low voltage auxiliary HEMT comprising a first auxiliary HEMT source terminal, a first auxiliary HEMT drain terminal, and a first auxiliary HEMT gate terminal;
wherein the first auxiliary HEMT source terminal is operatively connected to the high voltage HEMT gate terminal;
wherein the first auxiliary HEMT drain terminal is operatively connected to the control terminal; and
wherein the control circuit is configured such that modulation of the gate charge speed and timing for the high voltage HEMT is controllable via the first auxiliary HEMT gate terminal.

7. The semiconductor switch according to claim 6, wherein the control circuit further comprises an adjustable current source operatively connected to the first auxiliary HEMT gate terminal;
wherein the adjustable current source is configured to control a current feeding the first auxiliary HEMT gate terminal.

8. The semiconductor switch according to claim 6, wherein the control circuit further comprises a second low voltage auxiliary HEMT, the second low voltage auxiliary HEMT comprising a second auxiliary HEMT source terminal, a second auxiliary HEMT drain terminal, and a second auxiliary HEMT gate terminal;
wherein the control circuit is configured such that modulation of the gate charge speed and timing for the high voltage HEMT is additionally controllable via the second auxiliary HEMT gate terminal.

9. The semiconductor switch according to claim 8, wherein the first auxiliary HEMT gate terminal and the second auxiliary HEMT gate terminal are independently operable.

10. The semiconductor switch according to claim 8, wherein a switching speed of the second low voltage auxiliary HEMT is lower than a switching speed of the first low voltage auxiliary HEMT.

11. The semiconductor switch according to claim 2, wherein the control circuit is configured to detect the load condition by:
measuring a gate voltage of the high voltage transistor device, and
comparing the gate voltage with a reference voltage.

12. The semiconductor switch according to claim 11, wherein the control circuit comprises a second auxiliary HEMT operatively connected between the control terminal and the transistor device gate terminal.

13. The semiconductor switch according to claim 1, wherein the control circuit is configured to measure a gate voltage of the high voltage transistor device, and to delay a turn-off of the high voltage HEMT until the gate voltage of the high voltage transistor device falls below a threshold voltage level.

14. The semiconductor switch according to claim 1, comprising:
a sensing transistor connected in parallel with the high voltage HEMT and configured to sense a current or voltage through the high voltage HEMT; and
wherein the control circuit is configured to:
receive a sense signal from the sensing transistor and, when the sense signal is above a threshold sense signal, cause a turn-on speed of the high voltage HEMT to be reduced.

15. The semiconductor switch according to claim 6, wherein the control circuit comprises an adjustment transistor;
wherein a gate terminal of the adjustment transistor is configured to be controlled by the sense signal; and
wherein a drain terminal of the adjustment transistor is connected between the control terminal and the first auxiliary transistor source terminal such that the adjustment transistor controls a turn-on speed of the high voltage HEMT.

16. The semiconductor switch according to claim 1, wherein the control circuit is part of an interface circuit monolithically integrated with the high voltage HEMT.

17. The semiconductor switch according to claim 16, wherein the interface circuit is a III-nitride interface circuit.
